(19) United States
(12) Patent Application Publication
(10) Pub. No.: US 2026/0243980 A1
(43) Pub. Date: Aug. 20, 2026

(54) SEMICONDUCTOR PACKAGE AND METHODS OF MANUFACTURING THE SAME

(71) Applicant: Taiwan Semiconductor Manufacturing Company, Ltd., Hsinchu (TW)

(72) Inventors: Chia-Yen Tan, Taoyuan City (TW); Hung-Yi Kuo, Taipei City (TW); Yu-Min Liang, Taoyuan City (TW); Hao-Yi Tsai, Hsinchu City (TW)

(73) Assignee: Taiwan Semiconductor Manufacturing Company, Ltd., Hsinchu (TW)

(21) Appl. No.: 19/057,998

(22) Filed: Feb. 20, 2025

(51) Int. Cl. G02B 6/42; H01L 21/56; H01L 23/00; H01L 23/31; H01L 23/48; H01L 23/538; H01L 25/00; H01L 25/16; H10B 80/00

(52) U.S. Cl. CPC G02B 6/4251; H10W 70/611; H10W 74/01; H10W 90/00; H10W 90/401; H10B 80/00; H10W 20/20; H10W 74/141; H10W 74/15; H10W 90/724; H10W 90/734

(57) ABSTRACT

A semiconductor package includes an interposer, a first semiconductor die, and at least one optical die. The interposer includes a plurality of conductive pillars and at least one fiber socket, where the at least one fiber socket is arranged at an edge of the interposer, and a sidewall of the at least one fiber socket is part of a sidewall of the interposer. The first semiconductor die is disposed over and electrically coupled to the interposer. The at least one optical die is disposed over and electrically coupled to the interposer, where the at least one optical die is overlapped with the at least one fiber socket, and the at least one optical die is electrically communicated with the first semiconductor die through the interposer.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1, FIG. 2, FIG. 6, FIG. 7, FIG. 8, FIG. 10, FIG. 11, FIG. 12, FIG. 13, FIG. 14, FIG. 15, FIG. 18, FIG. 23 and FIG. 24 are schematic cross-sectional or plane views of various stages in manufacturing a semiconductor package in accordance with some embodiments of the disclosure.

FIG. 3 is a schematic and enlarged cross-sectional view showing a configuration of a bridge die in a semiconductor package in accordance with the disclosure.

FIG. 4 and FIG. 5 are respectively a schematic cross-sectional or plane view of a configuration of a fiber socket in a semiconductor package in accordance with the disclosure.

FIG. 9 is a schematic and enlarged cross-sectional view showing a configuration of an optical die in a semiconductor package in accordance with the disclosure.

FIG. 16 through FIG. 17 are schematic and enlarged cross-sectional views respectively showing various embodiments of a bonding configuration of a supporting structure, a bonding element and a substrate in a semiconductor package prior to removal of sacrificial layers in accordance with the disclosure.

FIG. 19 through FIG. 22 are schematic and enlarged cross-sectional views respectively showing various embodiments of a bonding configuration of a supporting structure, a bonding element and a substrate in a semiconductor package after removal of sacrificial layers in accordance with the disclosure.

FIG. 25 through FIG. 27 are respectively a schematic cross-sectional view of a semiconductor package in accordance with some alternative embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor package (or a semiconductor device or structure) having a stacked structure with an optical die (or chip/chiplet/package) and a fiber socket equipped therewith and a method of manufacturing the same, and is not intended to limit the scope of the disclosure. Due to the optical die with an edge coupler is directly integrated with the semiconductor package through an interposer included in the semiconductor package, a signal transmission path is reduced, thereby improving the performance of the semiconductor package by enabling the bandwidth enlargement, lower polarization sensitivity and faster data transfer. In addition, due to the fiber socket is integrated with the semiconductor package by embedding inside the interposer, the alignment and the placement of an optical fiber (e.g., a fiber array unit) can be accurate and precise, thereby improving the performance of the semiconductor package. The manufacture of such semiconductor package is compatible to the current and/or advanced manufacturing processes.

In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

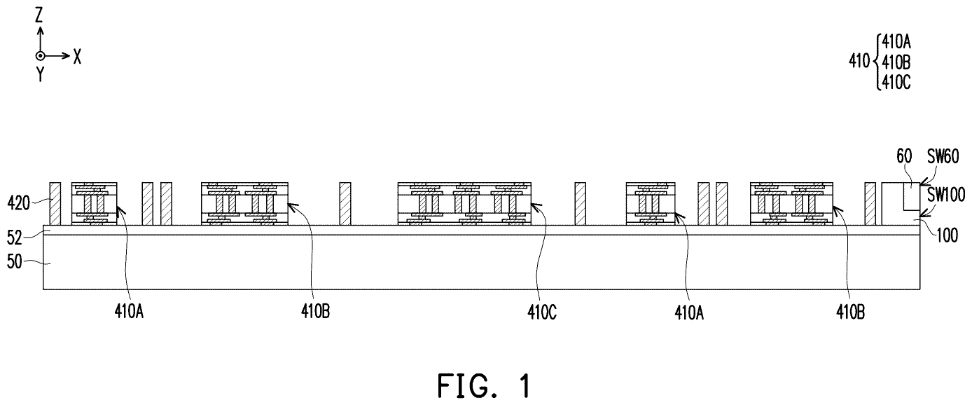

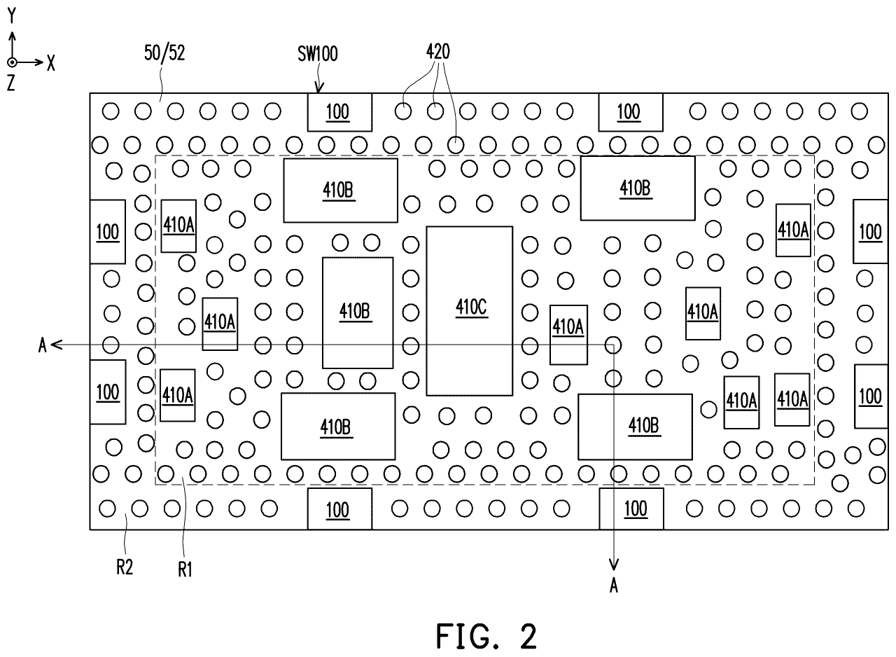

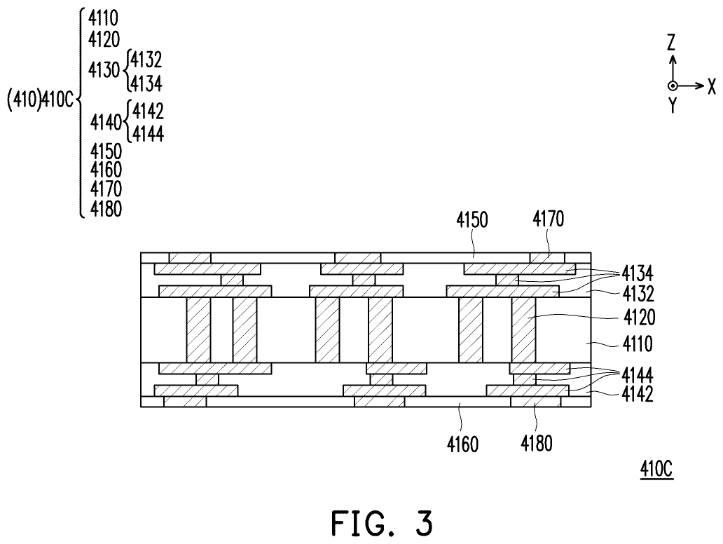

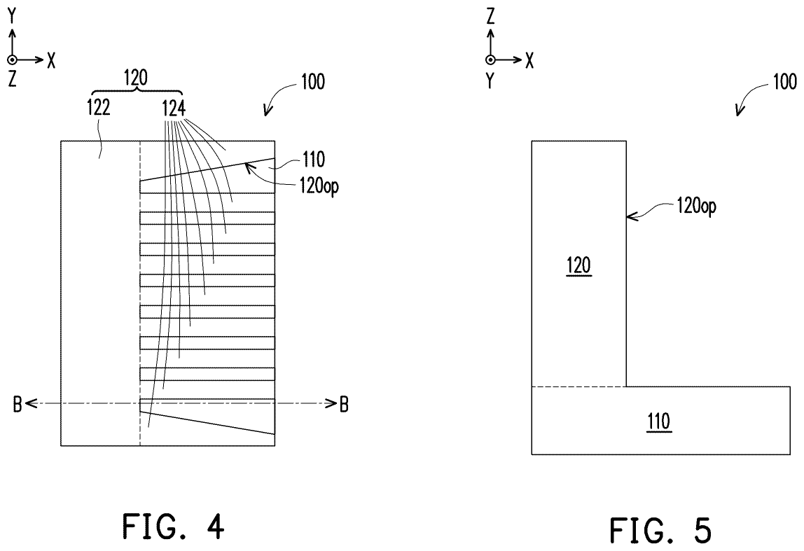

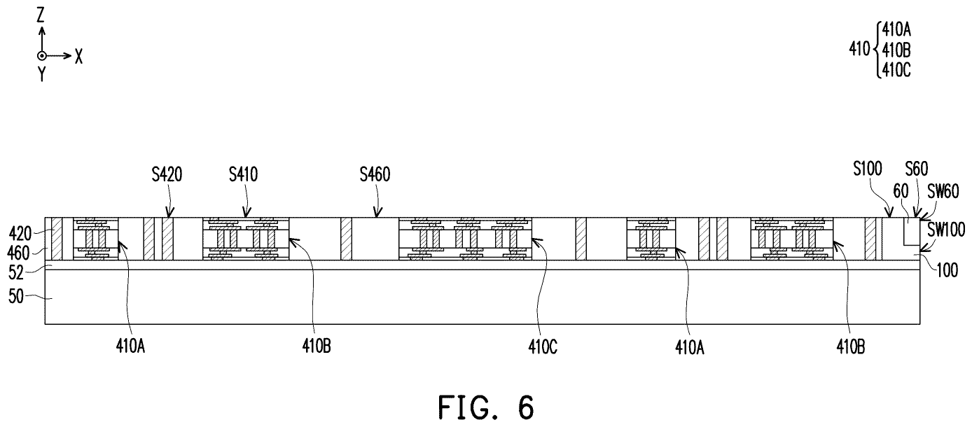

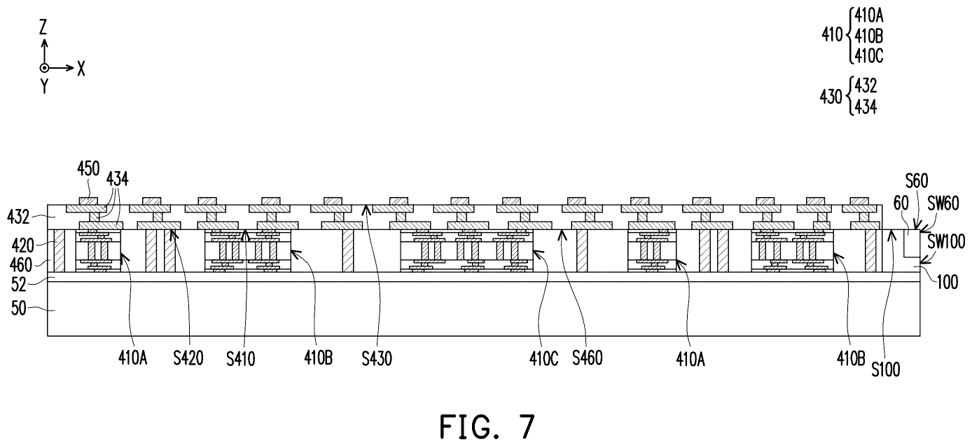

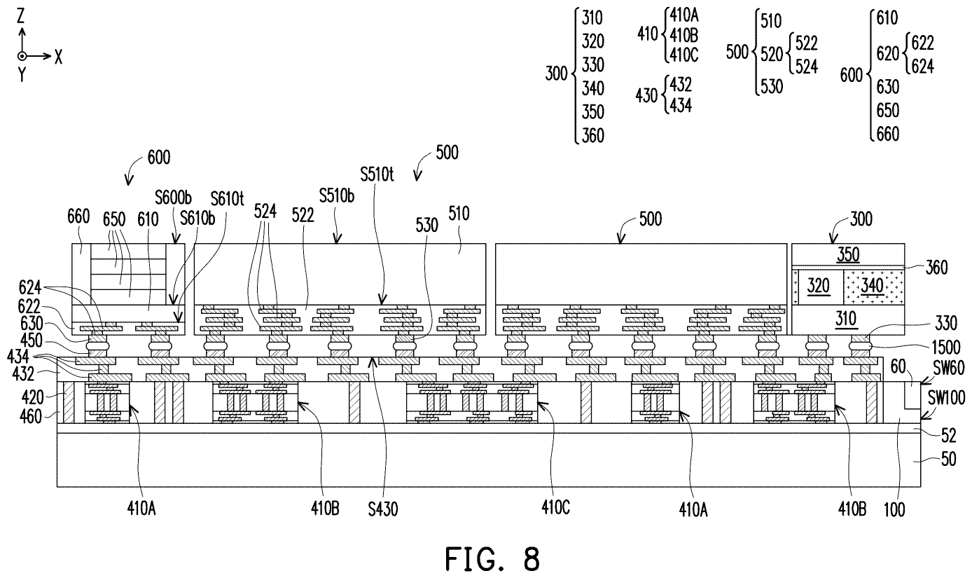

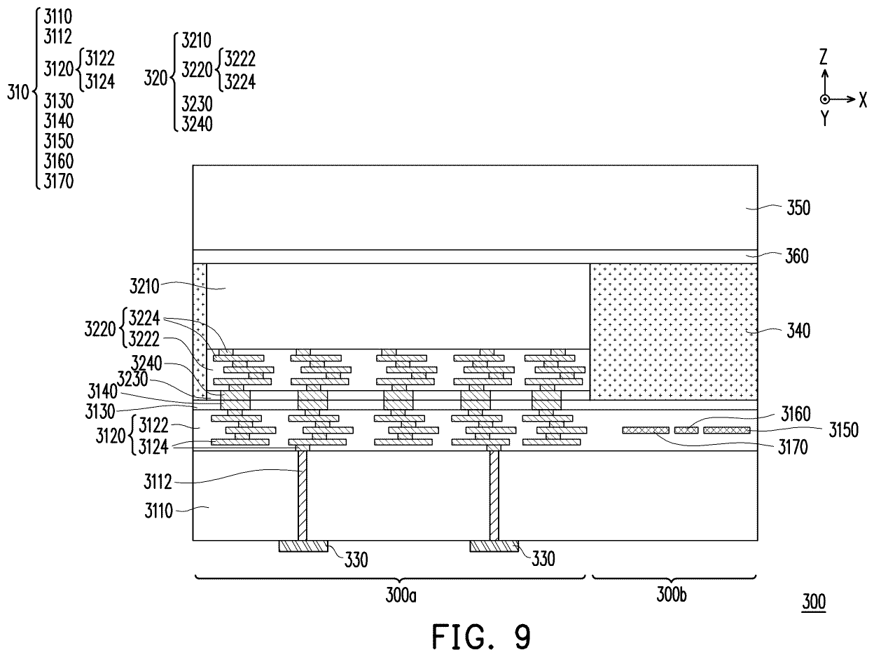

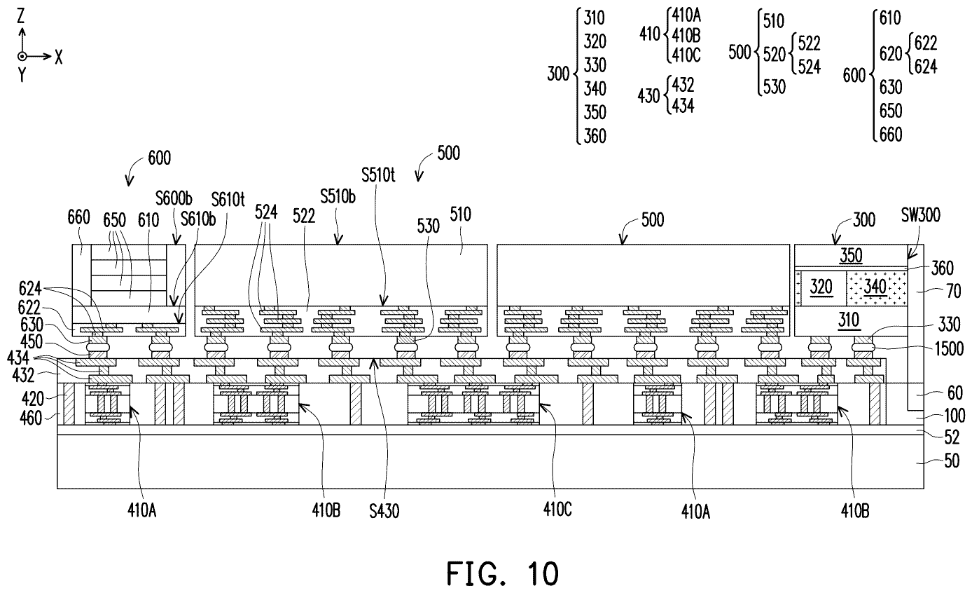

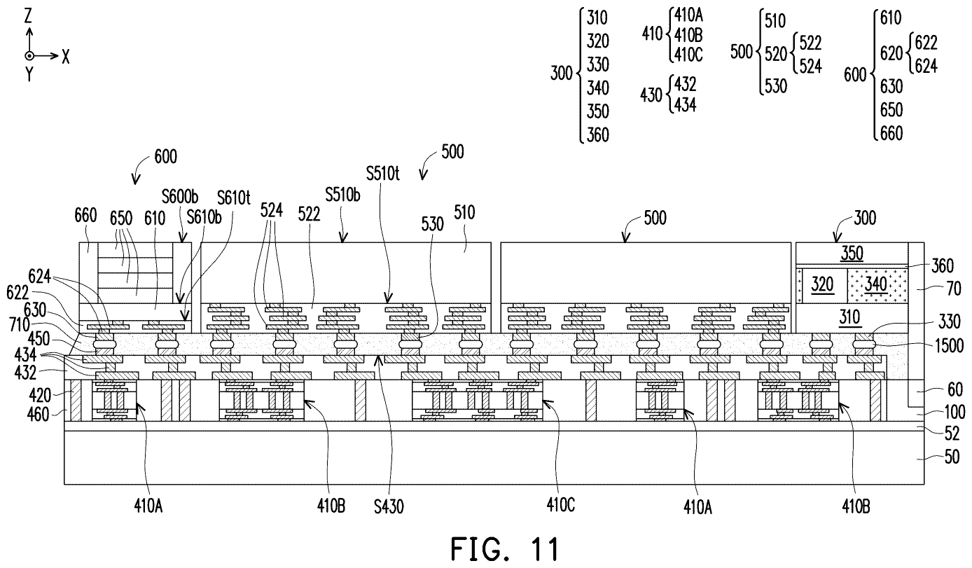

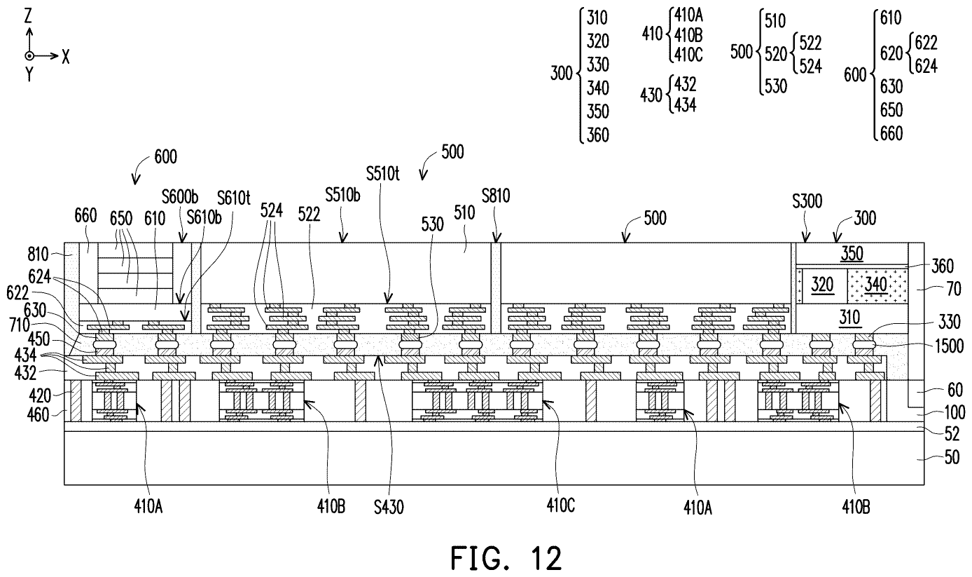

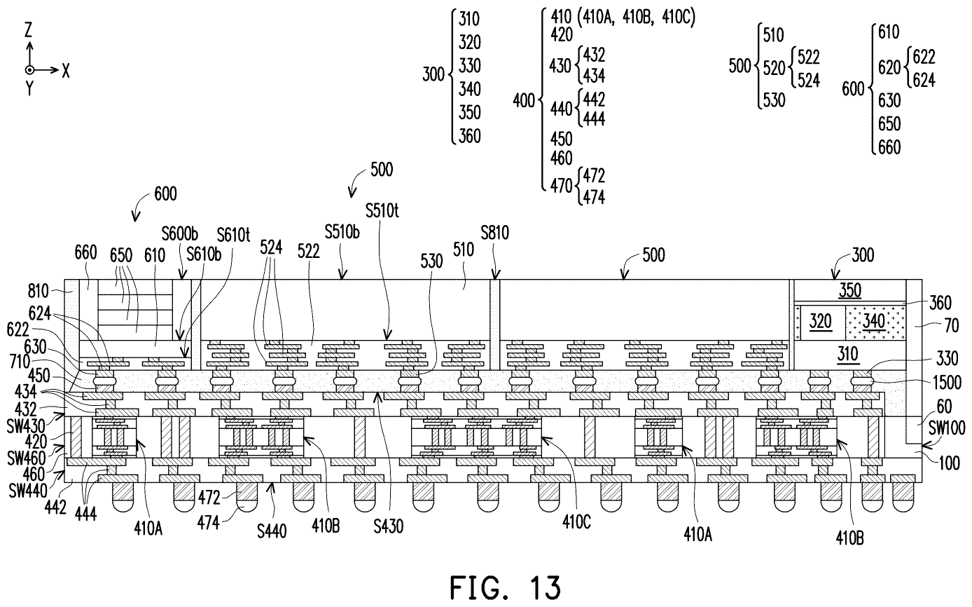

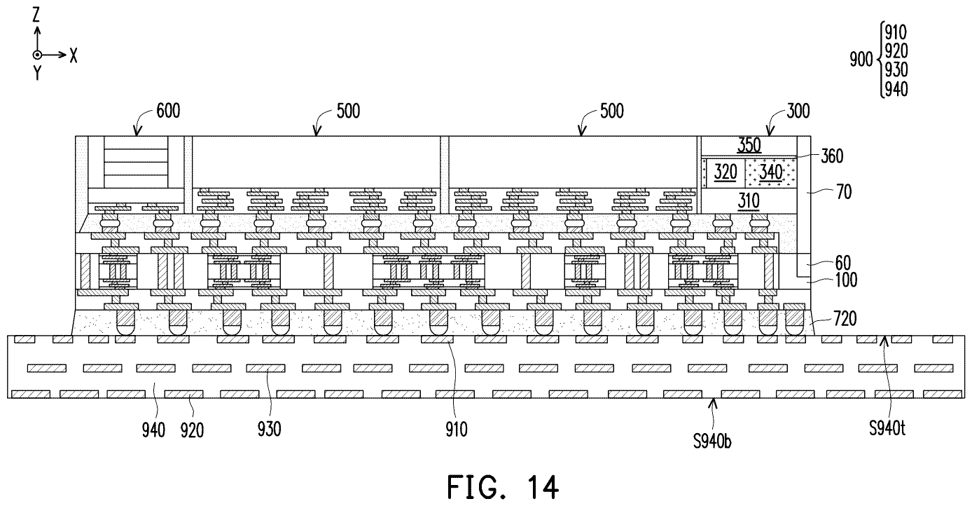

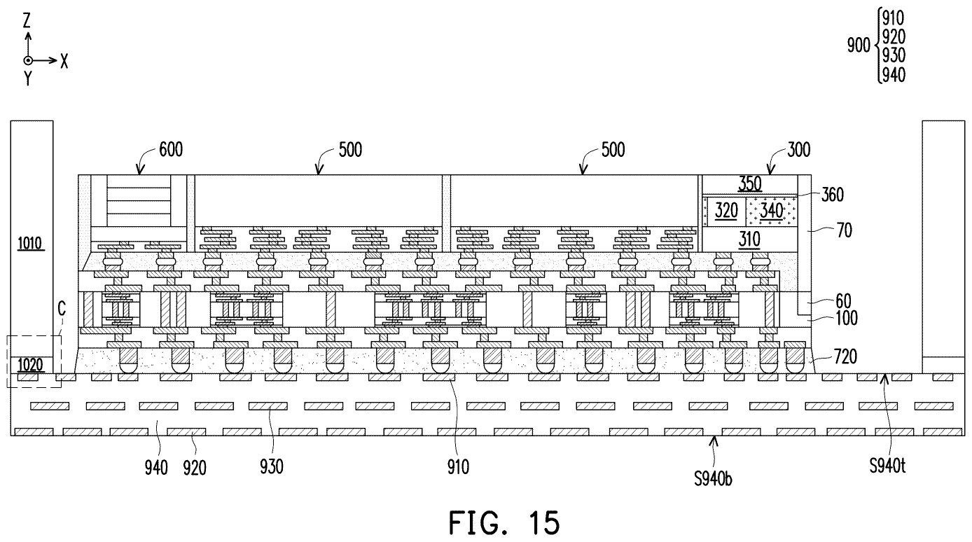

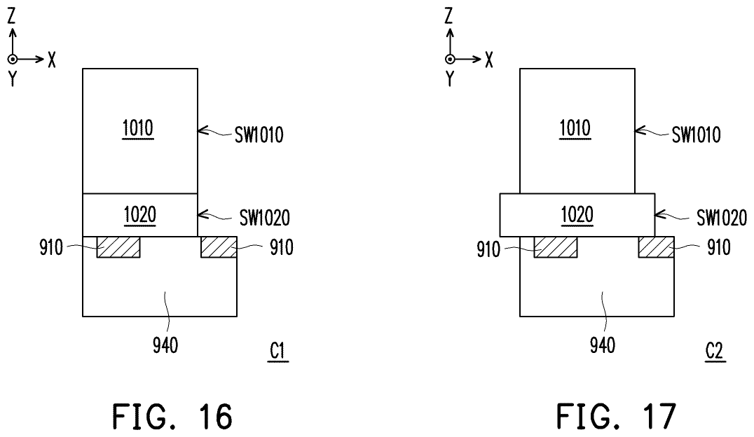

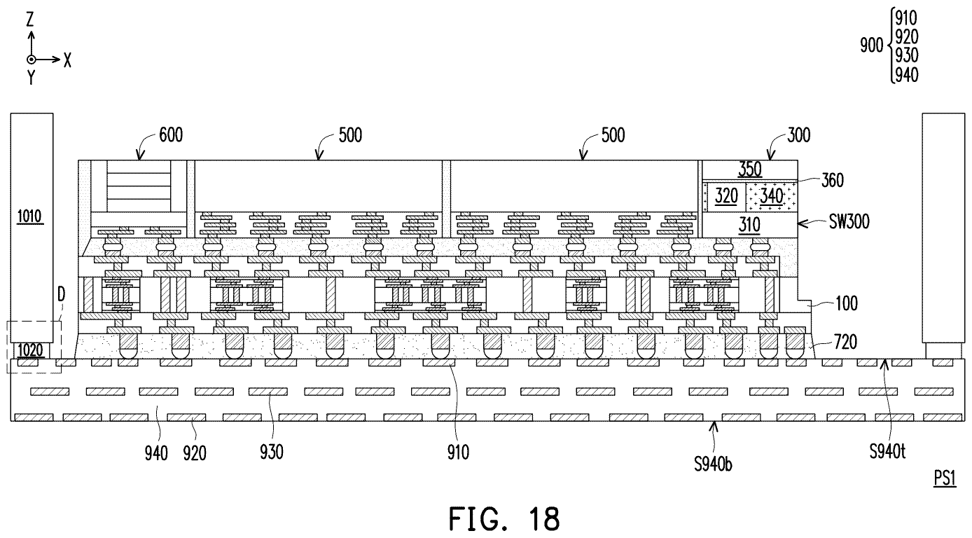

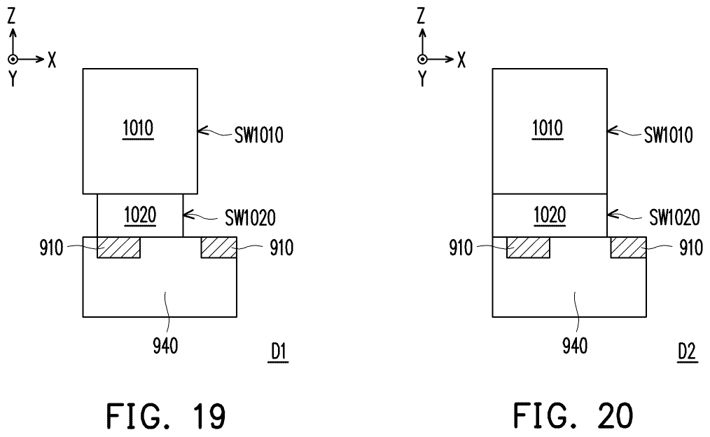

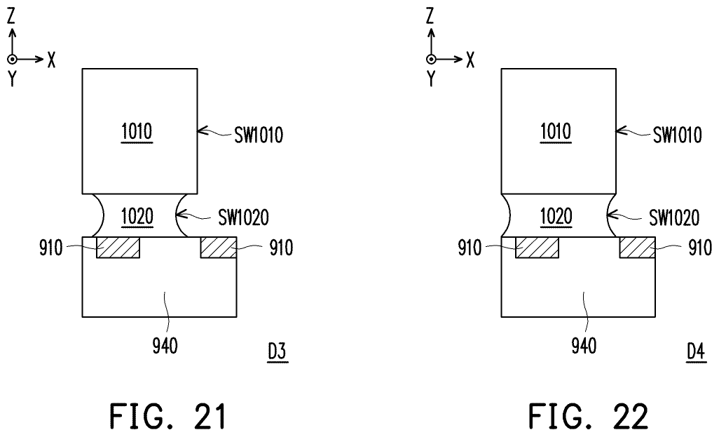

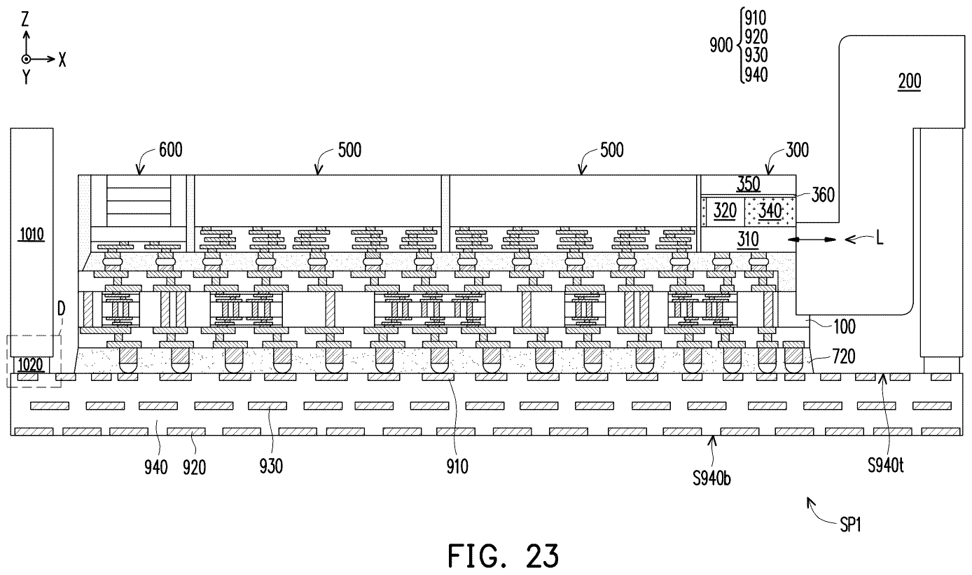

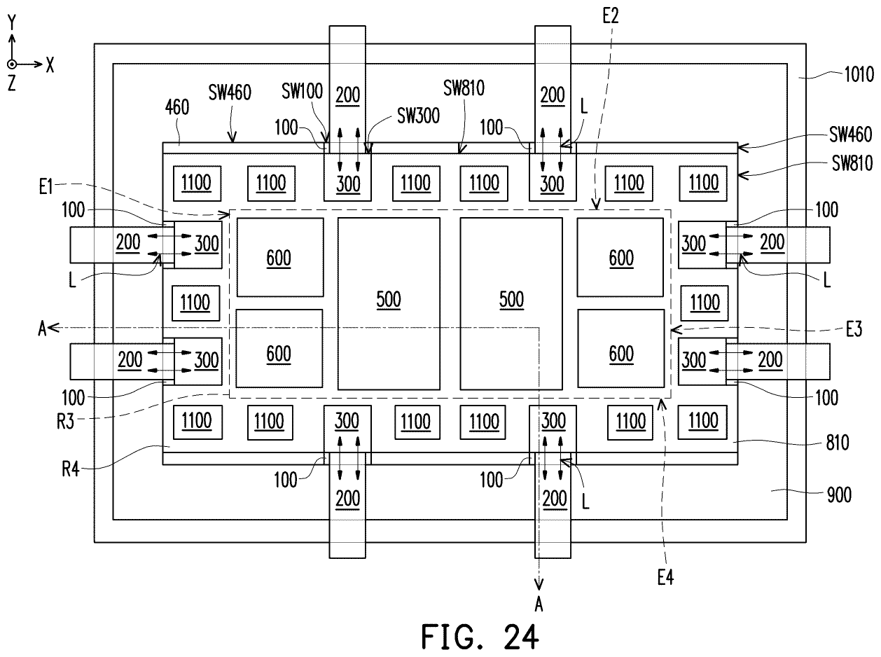

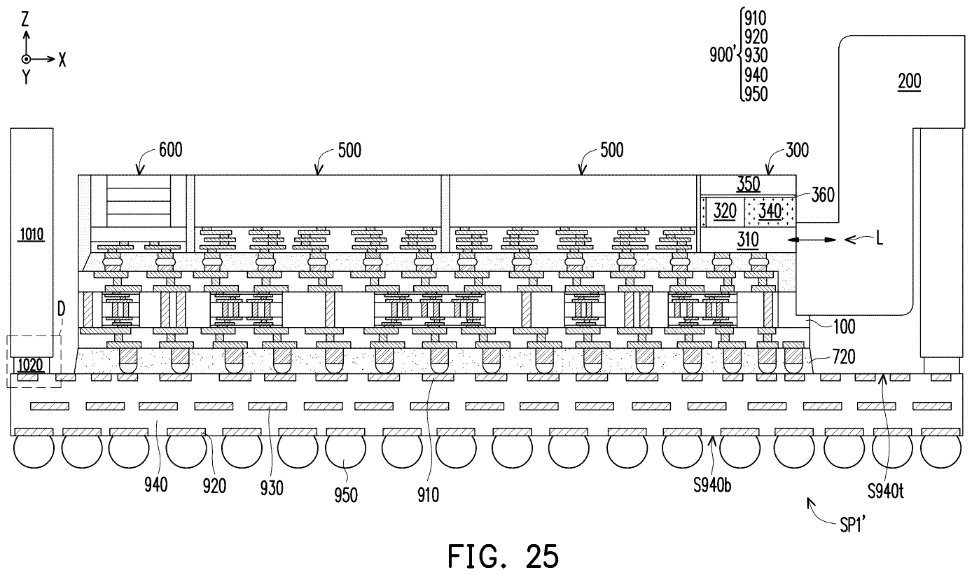

FIG. 1, FIG. 2, FIG. 6, FIG. 7, FIG. 8, FIG. 10, FIG. 11, FIG. 12, FIG. 13, FIG. 14, FIG. 15, FIG. 28, FIG. 23 and FIG. 24 are schematic cross-sectional or plane views of various stages in manufacturing a semiconductor package (e.g., SP1) in accordance with some embodiments of the disclosure, where the cross-sectional views of FIG. 1, FIG. 6, FIG. 7, FIG. 8, FIG. 10, FIG. 11, FIG. 12, FIG. 13, FIG. 14, FIG. 15, FIG. 18, and FIG. 23 are taken along a line AA depicted in the plane view of FIG. 2 and FIG. 24. FIG. 3 is a schematic and enlarged cross-sectional view showing a configuration of a bridge die (e.g., 410) in the semiconductor package (e.g., SP1). FIG. 4 and FIG. 5 are respectively a schematic cross-sectional or plane view of a configuration of a fiber socket (e.g., 100) in the semiconductor package (e.g., SP1), where the cross-sectional view of FIG. 5 is taken along the line AA depicted in FIG. 2 and a line BB depicted in FIG. 4. FIG. 9 is a schematic and enlarged cross-sectional view showing a configuration of an optical die (e.g., 300) in the semiconductor package (e.g., SP1). FIG. 16 through FIG. 17 are schematic and enlarged cross-sectional views respectively showing various embodiments of a bonding configuration of a supporting structure (e.g., 1010), a bonding element (e.g., 1020) and a substrate (e.g., 900) in the semiconductor package (e.g., SP1) prior to removal of sacrificial layers, which are outlined by a dashed-box C depicted in FIG. 15 (e.g., a dashed-box C1 in FIG. 16 and a d ashed-box C2 in FIG. 17). FIG. 19 through FIG. 22 are schematic and enlarged cross-sectional views respectively showing various embodiments of a bonding configuration of a supporting structure (e.g., 1010), a bonding element (e.g., 1020) and a substrate (e.g., 900) in the semiconductor package (e.g., SP1) after removal of sacrificial layers, which are outlined by a dashed-box D depicted in FIG. 18 (e.g., a dashed-box D1 in FIG. 19, a dashed-box D2 in FIG. 20, a dashed-box D3 in FIG. 21, and/or a dashed-box D4 in FIG. 22). FIG. 25 through FIG. 27 are respectively a schematic cross-sectional view of a semiconductor package (e.g., SP1′, SP2, or SP2′) in accordance with some alternative embodiments of the disclosure.

Referring to FIG. 1, in some embodiments, a carrier 50 coated with a release layer 52 is provided. The carrier 50 may include glass, metal, ceramic, silicon, plastic, combinations thereof, multi-layers thereof, or other suitable material that can provide structural support during the formation the semiconductor package SP1 in subsequent processing, in the disclosure. In some embodiments, the release layer 52 is used to hold components or layer later-formed on the carrier 50. The release layer 52 may be any material suitable for bonding and de-bonding the carrier 50 from the above layer(s) or any wafer(s) disposed thereon. In some embodiments, the release layer 52 includes a dielectric material layer made of a dielectric material including any suitable polymer-based dielectric material (such as benzocyclobutene (“BCB”), polybenzoxazole (“PBO”)). In an alternative embodiment, the release layer 52 includes a dielectric material layer made of an epoxy-based thermal-release material, which loses its adhesive property when heated, such as a light-to-heat-conversion (LTHC) release coating film. In a further alternative embodiment, the release layer 52 includes a dielectric material layer made of an ultra-violet (UV) glue, which loses its adhesive property when exposed to UV lights. The release layer 52 may be dispensed as a liquid and cured, or may be a laminate film laminated onto the carrier 50, or may be the like. The top surface of the release layer 52, which is opposite to a bottom surface contacting the carrier 50, may be levelled and may have a high degree of coplanarity. The release layer 52 is, for example, a LTHC layer with good chemical resistance, and such layer enables room temperature de-bonding from the carrier 50 by applying laser irradiation, however the disclosure is not limited thereto. Other suitable temporary adhesives may be used.

In some embodiments, a plurality of bridge dies 410 (e.g., including bridge dies 410A, 410B, and/or 410C), a plurality of conductive vias 420, and a plurality of fiber sockets 100 are provided and placed on the release layer 52 and over the carrier 50, as shown in FIG. 1 and FIG. 2. For example, the bridge dies 410, the conductive vias 420 and the fiber sockets 100 are placed onto the release layer 52 by pick-and-place process. For illustrative purposes, only two bridge dies 410A, two bridge dies 410B, one bridge dies 410C, eight conductive vias 420 and one fiber socket 100 are shown in FIG. 1, FIG. 6, FIG. 7, FIG. 8, FIG. 10, FIG. 11, FIG. 12, FIG. 13, FIG. 14, FIG. 15, FIG. 16, and FIG. 21 and only eight bridge dies 410A, four bridge dies 410B, one bridge dies 410C, and eight fiber sockets 100 are shown in FIG. 2, but the number of the bridge dies 410 (e.g., including bridge dies 410A, 410B, and/or 410C), the number of the conductive vias 420 and the number of the fiber socket 100 are not limited to the drawings, may be selected and designated based on the demand and design requirement. In some embodiments, the number of the fiber sockets 100 corresponds to the number of optical dies (e.g., 300 in FIG. 24). For example, the number of the fiber sockets 100 is equal to the number of optical dies (e.g., 300 in FIG. 24). For example, in the plane view of FIG. 2 and/or in the cross-sectional view of FIG. 1, a size of the bridge dies 410A is less than a size of the bridge dies 410B and a size of the bridge die(s) 410C, and the size of the bridge dies 410B is less than the size of the bridge die(s) 410C. In some embodiments, as shown in FIG. 1 and FIG. 3, the bridge dies 410A, 410B and 410C are substantially identical in the structure and functionality, except their lateral sizes (e.g., the dimensions in the X-Y plane). In some embodiments, over the release layer 52, there are a region R1 for the placements of the bridge dies 410 (such 410A, 410B, and/or 410C) and the placement of the conductive pillars 420 and a region R2 for then placement of the fiber sockets 100 and the placement of the conductive pillars 420, where the region R2 surrounds the region R1. In other words, the fiber sockets 100 are arranged along the edge of the release layer 52.

In a non-limiting embodiment of the bridge dies 410 as shown in FIG. 1 and FIG. where one bridge die 410C is emphasized as an example of a general structure of the bridge dies 410 (such as 410A, 410B and 410C), but the disclosure is not limited thereto. As shown in FIG. 3, the bridge die 410C may include a substrate 4110, a plurality of conductive pillars 4120 penetrating through the substrate 4110, an interconnect structure 4130 (including a dielectric structure 4132 and one or more metallization layers 4134) disposed over the substrate 4110 and electrically coupled to the conductive pillars 4120, an interconnect structure 4140 (including a dielectric structure 4142 and one or more metallization layers 4144) disposed over the substrate 4110 and electrically coupled to the conductive pillars 4120, a dielectric layer 4150 disposed over the interconnect structure 4130, a dielectric layer 4160 disposed over the interconnect structure 4140, a plurality of conductive vias 4170 disposed over and electrically coupled to the interconnect structure 4130 and laterally covered by the dielectric layer 4150, and a plurality of conductive vias 4180 disposed over and electrically coupled to the interconnect structure 4140 and laterally covered by the dielectric layer 4170, where the conductive vias 4170 penetrate through the dielectric layer 4150, and the conductive vias 4180 penetrate through the dielectric layer 4160. For example, an illustrated top surface of the dielectric layer 4150 is substantially level with illustrated top surfaces of the conductive vias 4170, and an illustrated top surface of the dielectric layer 4160 is substantially level with illustrated top surfaces of the conductive vias 4180. In other words, the illustrated top surface of the dielectric layer 4150 may be substantially coplanar to the illustrated top surfaces of the conductive vias 4170, and the illustrated top surface of the dielectric layer 4160 is substantially coplanar to the illustrated top surfaces of the conductive vias 4180. In alternative embodiments, the interconnect structure 4130 and/or the interconnect structure 4140 may be omitted. In addition to or alternative embodiments, the dielectric layer 4150 and/or the dielectric layer 4160 may be omitted. In addition to or alternative embodiments, the conductive vias 4170 and/or the conductive vias 4180 may be omitted.

In some embodiments, the substrate 4110 is a bulk semiconductor substrate, a silicon-on-insulator (SOI) substrate, a multi-layered semiconductor substrate, or the like. The semiconductor material of the substrate 4110 may be silicon, germanium; a compound semiconductor including silicon carbide, gallium arsenic, gallium phosphide, indium phosphide, indium arsenide, and/or indium antimonide; an alloy semiconductor including silicon germanium (SiGe), GaAsP, AlInAs, AlGaAs, GaInAs, GaInP, and/or GaInAsP; or combinations thereof. The alloy SiGe may be formed over a silicon substrate. The SiGe substrate may be strained. In an alternative embodiment, other substrates, such as multi-layered or gradient substrates, may also be used. The substrate 4110 may be doped or undoped. The substrate 4110 may include a wide variety of devices (not shown) (also referred to as semiconductor devices) formed therein. The devices may include active devices, passive devices, or a combination thereof. The devices may include integrated circuits devices. The devices may include transistors, capacitors, resistors, diodes, photodiodes, fuse devices, jumpers, inductors, or other similar devices. The functions of the devices may include memory, processors, sensors, amplifiers, power distribution, input/output circuitry, or the like. The devices each may be referred to as a semiconductor component. Alternatively, the substrate 4110 may be substantially free of active devices and passive devices, and merely provide routing functions.

In some embodiments, the through vias 4120 are formed in the substrate 4110 and penetrating through the substrate 4110. The through vias 4120 may be sometimes referred to as through-substrate-vias or through-silicon-vias as the substrate 4110 is a silicon substrate. The through vias 4120 may be formed by forming recesses in the substrate 4110 (by, for example, etching, milling, laser techniques, a combination thereof, and/or the like) and depositing a conductive material in the recesses. The conductive material may be formed by an electro-chemical plating process, a chemical vapor deposition (CVD), an atomic layer deposition (ALD), a physical vapor deposition (PVD), a combination thereof, and/or the like. Examples of conductive materials are copper, tungsten, aluminum, silver, gold, a combination thereof, and/or the like. An optional thin dielectric material may be formed in the recesses, such as by using an oxidation technique, to separate the substrate 4110 and the through vias 4120. A thin barrier layer may be conformally formed in the recesses, such as by CVD, ALD, PVD, thermal oxidation, a combination thereof, and/or the like, to separate the substrate 4110 and the optional thin dielectric material. The barrier layer may include a nitride or an oxynitride, such as titanium nitride, titanium oxynitride, tantalum nitride, tantalum oxynitride, tungsten nitride, a combination thereof, and/or the like. Excess conductive material and barrier layer is removed from an illustrated top surface of the substrate 4110 by, for example, chemical mechanical polishing (CMP) process. Thus, the through vias 4120 may include a conductive material, a thin barrier layer between the conductive material and the substrate 4110 and an optional dielectric layer between the thin barrier layer and the substrate 4110. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc. The number of the through vias 4120 is not limited to the drawings of the disclosure, and may be designated and selected based on the demand and design layout. The through vias 4120 may be sometimes referred to as through-substrate-vias or through-silicon-vias as the substrate 4110 is a silicon substrate.

In some embodiments, the redistribution circuit structure 4130 is formed on the illustrated top surface (not labeled) of the substrate 4110, and is electrically connected to the substrate 4110. In certain embodiments, the redistribution circuit structure 4130 includes a dielectric structure 4132 and one or more metallization layers 4134 arranged therein for providing routing functionality. For example, the dielectric structure 4132 includes one or more dielectric layers, such that the dielectric layers and the metallization layer 4134 are sequentially formed, and one metallization layer 4134 is sandwiched between two dielectric layers. As shown in FIG. 3, portions of an illustrated top surface of a topmost layer of the metallization layers 4134 may be respectively exposed by a topmost portion (e.g., a topmost dielectric layer) of the dielectric structure 4132, and portions of an illustrated bottom surface of a bottommost layer of the metallization layers 4134 may be respectively exposed by a bottommost portion (e.g., a bottommost dielectric layer) of the dielectric structure 4132; however, the disclosure is not limited thereto. For example, the illustrated top surface (not labeled) of the topmost layer of the metallization layers 4134 is substantially level with an illustrated top surface (not labeled) of the topmost dielectric layer of the dielectric structure 4132. In such case, the illustrated top surface (not labeled) of the topmost layer of the metallization layers 4134 may be substantially coplanar to the illustrated top surface (not labeled) of the topmost dielectric layer of the dielectric structure 4132. On the other hand, for example, the illustrated bottom surface (not labeled) of the bottommost layer of the metallization layers 4134 is substantially level with an illustrated bottom surface (not labeled) of the bottommost dielectric layer of the dielectric structure 4132. In such case, the illustrated bottom surface (not labeled) of the bottommost layer of the metallization layers 4134 may be substantially coplanar to the illustrated bottom surface (not labeled) of the bottommost dielectric layer of the dielectric structure 4132.

In some embodiments, a redistribution circuit structure 4140 is formed on the illustrated bottom surface (not labeled) of the substrate 4110, and is electrically connected to the substrate 4110. In certain embodiments, the redistribution circuit structure 4140 includes a dielectric structure 4142 and one or more metallization layers 4144 arranged therein for providing routing functionality. For example, the dielectric structure 4142 includes one or more dielectric layers, such that the dielectric layers and the metallization layer 4144 are sequentially formed, and one metallization layer 4144 is sandwiched between two dielectric layers. As shown in FIG. 3, portions of an illustrated top surface of a topmost layer of the metallization layers 4144 may be respectively exposed by a topmost portion (e.g., a topmost dielectric layer) of the dielectric structure 4142, and portions of an illustrated bottom surface of a bottommost layer of the metallization layers 4144 may be respectively exposed by a bottommost portion (e.g., a bottommost dielectric layer) of the dielectric structure 4142; however, the disclosure is not limited thereto. For example, the illustrated top surface (not labeled) of the topmost layer of the metallization layers 4144 is substantially level with an illustrated top surface (not labeled) of the topmost dielectric layer of the dielectric structure 4142. In such case, the illustrated top surface (not labeled) of the topmost layer of the metallization layers 4144 may be substantially coplanar to the illustrated top surface (not labeled) of the topmost dielectric layer of the dielectric structure 4142. On the other hand, for example, the illustrated bottom surface (not labeled) of the bottommost layer of the metallization layers 4144 is substantially level with an illustrated bottom surface (not labeled) of the bottommost dielectric layer of the dielectric structure 4142. In such case, the illustrated bottom surface (not labeled) of the bottommost layer of the metallization layers 4144 may be substantially coplanar to the illustrated bottom surface (not labeled) of the bottommost dielectric layer of the dielectric structure 4142.

The material of the dielectric structures 4132, 4142 may include silicon oxide, silicon nitride, silicon oxy-nitride, or any other suitable dielectric materials, and may be formed by deposition or the like. The metallization layers 4134, 4144 may be or include patterned copper layers or other suitable patterned metal layers, and may be formed by electroplating or deposition. However, the disclosure is not limited thereto. Alternatively, the metallization layers 4134, 4144 may be formed by single or dual-damascene method. The numbers of the metallization layers and the dielectric layers included in each of the redistribution circuit structures 4130, 4140 is not limited to the drawings of the disclosure, and may be designated and selected based on the demand and design layout.

The through vias 4120 may be connected to the portions of the illustrated bottom surface of the bottommost layer of the metallization layers 4134 respectively exposed by the bottommost dielectric layer of the dielectric structure 4132 and the portions of the illustrated top surface of the topmost layer of the metallization layers 4144 respectively exposed by the topmost dielectric layer of the dielectric structure 4142, as shown in FIG. 1 and FIG. 3. In other words, the redistribution circuit structure 4130 is electrically connected to the redistribution circuit structure 4140 through the through vias 4120. The redistribution circuit structures 4130, 4140 independently may further be electrically connected to the active and/or passive devices in the substrate 4110 (if any) by direct contacts therebetween. In some embodiments, through the redistribution circuit structures 4130 and/or 4140, the through vias 4120 are electrically coupled to the active and/or passive devices in of the substrate 4110 (if any).

In some embodiments, the dielectric layer 4150 is formed on the redistribution circuit structure 4130, where the redistribution circuit structure 4130 is disposed between the substrate 4110 and the dielectric layer 4150 and between the through vias 4120 and the dielectric layer 4150. As shown in FIG. 3, portions of the redistribution circuit structure 4130 may be exposed by a plurality of openings (not labeled) formed in the dielectric layer 4150. For example, the portions of the illustrated top surface of the topmost layer of the metallization layers 4134 respectively exposed by the topmost dielectric layer of the dielectric structure 4132 are further accessibly revealed by the openings formed in the dielectric layer 4150 for electrical connections to later-formed components (e.g., the conductive vias 4170). In some embodiments, the dielectric layer 4160 is formed on the redistribution circuit structure 4140, where the redistribution circuit structure 4140 is disposed between the substrate 4110 and the dielectric layer 4160 and between the through vias 4120 and the dielectric layer 4160. As shown in FIG. 3, portions of the redistribution circuit structure 4140 are exposed by a plurality of openings (not labeled) formed in the dielectric layer 4160. For example, the portions of the illustrated bottom surface of the bottommost layer of the metallization layers 4144 respectively exposed by the bottommost dielectric layer of the dielectric structure 4142 are further accessibly revealed by the openings formed in the dielectric layer 4160 for electrical connections to later-formed components (e.g., the conductive vias 4180). The dielectric layers 4150 and 4160 may be formed by deposition and patterning processes. The patterning process may include an etching process, such a dry etching process, a wet etching process, or the combination thereof. In one embodiment, the material of the conductive vias 4170, 4180 includes a metal material such as copper or copper alloys, or the like. The conductive vias 4170 and 4180 may be formed by photolithography, deposition/plating, photoresist stripping processes or any other suitable method. The plating process may include an electroplating plating, an electroless plating, or the like.

In a non-limiting example, after the formation of the dielectric layer 4150, the conductive vias 4170 are formed by, but not limited to, forming a mask pattern (not shown) covering the dielectric layer 4150 with opening holes (not labeled) corresponding to the portions of the illustrated top surface of the topmost layer of the metallization layers 4134 respectively exposed by the topmost dielectric layer of the dielectric structure 4132 exposed by the openings formed in the dielectric 4150; forming a metallic material to fill the openings formed in the dielectric layer 4150 to form the conductive vias 4170 by electroplating or deposition; and then removing the mask pattern. The mask pattern may be removed by acceptable ashing process and/or photoresist stripping process, such as using an oxygen plasma or the like.

An optional seed layer (not shown) may be formed before forming the conductive vias 4170 and after the formation of the dielectric layer 4150 so to facilitate the formation of the conductive vias 4170. In a non-limiting example, the conductive vias 4170 and the dielectric layer 4150 may be formed by, but not limited to, forming a blanket layer of dielectric material over the redistribution circuit structure 4130; patterning the dielectric material blanket layer to form the dielectric layer 4150 having a plurality of openings (not labeled) penetrating through the dielectric layer 4150 and accessibly revealing portions of the illustrated top surface of the exposed topmost layer of the metallization layers 4134; optionally forming a blanket layer of seed layer material over the dielectric layer 4150, the seed layer material blanket layer extending into the openings formed in the dielectric layer 4150 to line the openings and in contact with the exposed portions of the illustrated top surface of the exposed topmost layer of the metallization layers 4134; forming a blanket layer of a conductive material over the seed layer material blanket layer and to fill the openings formed in the dielectric layer 4150; patterning the conductive material blanket layer to form the conductive vias 4170; using the conductive vias 4170 as etching mask to pattern the seed layer material blanket layer and form a respective optional seed layer underneath thereto. However, the disclosure is not limited thereto.

In some embodiments, the optional seed layer is a metal layer, which may be a single layer or a composite layer including a plurality of sub-layers formed of different materials. In some embodiments, the optional seed layer includes a titanium layer and a copper layer over the titanium layer, or two titanium layers and a cupper layer sandwiched between the two titanium layers. The optional seed layer may be formed using, for example, sputtering or the like. Similarly, optional seed layers (not shown) may be adapted to facilitate the formation of the metallization layers 4134, 4144, if needed. The formation and material of conductive vias 4180 are similar to or substantially identical to the formation and material of the conductive vias 4170, and thus are not repeated herein.

The bridge die 410 (e.g., 410A, 410B, and/or 410C) may be referred to as a local silicon interconnection (LSI) die or interconnecting die. In some embodiments, the conductive vias 420 are pre-fabricated conductive pillars. However, the disclosure is not limited thereto.

In some embodiments, as shown in FIG. 4 and FIG. 5 in conjunction with FIG. 1, the fiber sockets 100 are pre-fabricated. In a non-limiting embodiment of the fiber socket 100 as shown in FIG. 4 (e.g., a plane view of the fiber socket 100) and FIG. 5 (e.g., a cross-section view of the socket 100 taken along the line BB depicted in FIG. 4), where one fiber socket 100 is emphasized as an example of a general structure of the fiber sockets 100, but the disclosure is not limited thereto. In some embodiments, the fiber socket 100 includes a base 110 and an engaging structure 120 standing on the base 110, where the base 110 and the engaging structure 120 are physically connected to each other. For example, the base 110 and the engaging structure 120 are an integral piece. The engaging structure 120 has a first portion 122 and a plurality of second portions 124 connecting to the first portion 122, where the second portions 124 are spacing apart from each other by openings 120op, for example. As shown in FIG. 4 and FIG. 5, the second portions 124 may be laterally protruded away from a side of the first portion 122. In some embodiments, in the plane view of FIG. 4, shapes of the second portions 124 may be rectangular, trapezoid, or a combination thereof, the disclosure is not limited thereto. In a vertical projection along the direction Z, a shape of the engaging structure may be a comb-like shape, as shown in FIG. 4.

The fiber sockets 100 may be formed by, but not limited to, providing a silicon bulk with a plurality of regions for forming the fiber sockets 100; patterning the silicon bulk to form an engaging structure 120 having the openings 120op and standing on a base 110 within a respective region of the regions, the bases 110 in the regions being physically connected to each other; and separating the regions by cutting through the silicon bulk to form a plurality of separate and individual fiber sockets 100. However, the disclosure is not limited thereto. The fiber sockets 100 may be referred to as silicon (Si) receptacles.

Back to FIG. 1, in some embodiments, after placing the bridge dies 410, the conductive pillars 420 and the fiber sockets 100 on the release layer 52 over the carrier 50, the fiber sockets 100 are respectively protected by a sacrificial layer 60. For example, for each fiber socket 100, the sacrificial layer 60 is disposed on the base 110 and filled in the openings 120op to protected the engaging structure 120. The sacrificial layers 60 may be formed on the fiber sockets 100 by filling the openings 120op with a sacrificial material through dispensing process. The sacrificial material forming the sacrificial layers 60 may include polymer, such as acrylic resin, novolak resin, or the like. In the disclosure the sacrificial layers 60 may be referred to as sacrificial features, a protective layers/features or protective polymer layers/features.

Referring to FIG. 6, in some embodiments, after forming the sacrificial layers 60 on the fiber sockets 100, the bride dies 410 (e.g., 410A, 410B and 410B), the conductive pillars 420, the fiber sockets 100 and the sacrificial layers 60 are encapsulated in an encapsulant 460, where an illustrated top surface (e.g., a surface S460) of the insulating encapsulant 460 is substantially level with illustrated top surfaces (e.g., surfaces S410) of the bridge dies 410, illustrated top surfaces (e.g., surfaces S420) of the conductive pillars 420, illustrated top surfaces (e.g., surfaces S100) of the fiber sockets 100 and illustrated top surfaces (e.g., surfaces S60) of the sacrificial layers 60. In other words, the illustrated top surface (e.g., the surface S460) of the insulating encapsulant 460 is substantially coplanar to the illustrated top surfaces (e.g., the surfaces S410) of the bridge dies 410, the illustrated top surfaces (e.g., the surfaces S420) of the conductive pillars 420, the illustrated top surfaces (e.g., the surfaces S100) of the fiber sockets 100 and the illustrated top surfaces (e.g., the surfaces S60) of the sacrificial layers 60. That is, the bridge dies 410, the conductive pillars 420, the fiber sockets 100 and the sacrificial layers 60 are accessibly revealed by the insulating encapsulant 460. The insulating encapsulant 460 may be referred to as an insulating encapsulation, encapsulation, or encapsulant.

For example, the insulating encapsulant 460 laterally encapsulates the bridge dies 410, the conductive pillars 420 and the fiber sockets 100 protected by the sacrificial layers 60 and covers the release layer 52 exposed therefrom. In some embodiments, the insulating encapsulant 460 is a molding compound formed by a molding process. In some embodiments, the insulating encapsulant 460 include polymers (such as epoxy resins, phenolic resins, silicon-containing resins, or other suitable resins), dielectric materials, or other suitable materials. In an alternative embodiment, the insulating encapsulant 460 may include an acceptable insulating encapsulant material. The insulating encapsulant 460 may further include inorganic filler or inorganic compound (e.g., silica, clay, and so on) which can be added therein to optimize coefficient of thermal expansion (CTE) of the insulating encapsulant 460, the disclosure is not limited thereto. The insulating encapsulant 460 may be referred to as an encapsulant, a dielectric encapsulant, or an encapsulant. For example, the insulating encapsulant 460 is formed by, but not limited to, over-molding the bridge dies 410, the conductive pillars 420 and the fiber sockets 100 protected by the sacrificial layers 60 by an insulating encapsulant material, and patterning the insulating encapsulant material to form the insulating encapsulant 460. The insulating encapsulant material may be patterned by a planarizing process until obtaining a substantially flat and planar surface therefrom (e.g., S460). Owing to the insulating encapsulant 460, the bridge dies 410, the conductive pillars 420 and the fiber sockets 100 protected by the sacrificial layers 60 are protected from the damages caused by the external contacts.

The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method. For example, sidewalls SW60 of the sacrificial layers 60 and sidewalls SW100 of the fiber sockets 100 are substantially aligned to each other, and are both exposed by the insulating encapsulant 460. This is to say, a sidewall SW460 of the insulating encapsulant 460 and the sidewalls SW100 of the fiber sockets 100 are substantially aligned, see FIG. 24.

Referring to FIG. 7, in some embodiments, a redistribution circuit structure 430 is formed on the surface S460 of the insulating encapsulant 460 and extends onto the bridge dies 410 (e.g., 410A, 410B and/or 410C) and the conductive pillars 420. The redistribution circuit structure 430 may be electrically coupled to the bridge dies 410 (e.g., 410A, 410B and/or 410C) and the conductive pillars 420, as shown in FIG. 7. For example, the redistribution circuit structure 430 is free from the fiber sockets 100 and the sacrificial layers 60 disposed thereon. In other words, the redistribution circuit structure 430 is not disposed on (e.g., no in physical contact with) the surfaces S100 of the fiber sockets 100 and the surfaces S60 of the sacrificial layers 60.

In some embodiments, the redistribution circuit structure 430 includes a dielectric structure 432 and one or more metallization layers 434 arranged therein for providing routing functionality. For example, the dielectric structure 432 includes one or more dielectric layers, such that the dielectric layers and the metallization layer 434 are sequentially formed, and one metallization layer 434 is sandwiched between two dielectric layers. As shown in FIG. 7, portions of an illustrated top surface of a topmost layer of the metallization layers 434 may be respectively exposed by a topmost portion (e.g., a topmost dielectric layer) of the dielectric structure 432, and portions of an illustrated bottom surface of a bottommost layer of the metallization layers 434 may be respectively exposed by a bottommost portion (e.g., a bottommost dielectric layer) of the dielectric structure 432; however, the disclosure is not limited thereto. For example, the illustrated top surface (not labeled) of the topmost layer of the metallization layers 434 is substantially level with an illustrated top surface (not labeled) of the topmost dielectric layer of the dielectric structure 432. In such case, the illustrated top surface (not labeled) of the topmost layer of the metallization layers 434 may be substantially coplanar to the illustrated top surface (not labeled) of the topmost dielectric layer of the dielectric structure 432. On the other hand, for example, the illustrated bottom surface (not labeled) of the bottommost layer of the metallization layers 434 is substantially level with an illustrated bottom surface (not labeled) of the bottommost dielectric layer of the dielectric structure 432. In such case, the illustrated bottom surface (not labeled) of the bottommost layer of the metallization layers 434 may be substantially coplanar to the illustrated bottom surface (not labeled) of the bottommost dielectric layer of the dielectric structure 432. The details, formation and material of each of the redistribution circuit structure 430 are respectively similar to or substantially identical to the details, formation and material of the redistribution circuit structure 4130 or 4140 previously described in FIG. 1 and FIG. 3, and thus are not repeated herein for brevity.

In addition, prior to forming the redistribution circuit structure 430, the fiber sockets 100 and the sacrificial layers 60 may be covered by a sacrificial feature (not shown), so to constrain the positioning location of the redistribution circuit structure 430 (which being away from the fiber sockets 100 and the sacrificial layers 60). After forming the redistribution circuit structure 430, the sacrificial feature is removed, and the fiber sockets 100 and the sacrificial layers 60 are accessibly exposed from the redistribution circuit structure 430, for example. In some embodiments, the sacrificial feature includes a photoresist layer/feature or a lamination layer/film, which can be removed easily from the fiber sockets 100 and the sacrificial layers 60. The disclosure is not limited the material of the sacrificial feature; as long as during the removal of the sacrificial feature, the redistribution circuit structure 430, the fiber sockets 100 and the sacrificial layers 60 are un-removed (e.g., being inert during the removing process of the sacrificial feature). In some embodiments, the material of the sacrificial feature is different from the material of the sacrificial layers 60 and the fiber sockets 100.

Back to FIG. 7, in some embodiments, a plurality of conductive vias 450 are disposed over and electrically coupled to the redistribution circuit structure 430, where the redistribution circuit structure 430 is disposed between the conductive vias 450 and the encapsulant 460. For example, some of the conductive vias 450 may be electrically coupled to the bridge dies 410A through the redistribution circuit structure 430, some of the conductive vias 450 may be electrically coupled to the bridge dies 410B through the redistribution circuit structure 430, and some of the conductive vias 450 may be electrically coupled to the bridge dies 410C through the redistribution circuit structure 430. For example, some of the conductive vias 450 may be electrically coupled to the conductive pillars 420 through the redistribution circuit structure 430. The details, formation and material of the conductive vias 450 are respectively similar to or substantially identical to the details, formation and material of the conductive vias 4170 and/or 4180 previously described in FIG. 1 and FIG. 3, and thus are not repeated herein for brevity.

Referring to FIG. 8, in some embodiments, a plurality of optical dies 300, a plurality of semiconductor dies 500, a plurality of semiconductor dies 600, and a plurality of semiconductor dies 1100 are provided and placed over the redistribution circuit structure 430. In some embodiments, in a vertical portion (e.g., the X-Y plane shown in FIG. 24) along the direction Z, there are a region R3 for the placements of the semiconductor dies 500 and 600 and a region R4 for then placement of the optical dies 300 and the placement of the semiconductor dies 1100, where the region R4 surrounds the region R3. In other words, the optical dies 300 and the semiconductor dies 1100 are arranged along the edge of the release layer 52. For example, the semiconductor dies 600 are arranged at two opposites sides of the semiconductor dies 500, and the semiconductor dies 1100 and the optical dies 300 are arranged along edges E1, E2, E3 and E4 of the region R3, see FIG. 8 in conjunction with FIG. 24. The disclosure is not limited thereto; alternatively, the semiconductor dies 600 may be arranged at two opposites sides of the semiconductor dies 500, where the optical dies 300 may be arranged along one edge of the edges E1, E2, E3 and E4 of the region R3, and the semiconductor dies 1100 may be arranged along the rest of the edges E1, E2, E3 and E4 of the region R3. Alternatively, the semiconductor dies 600 may be arranged at two opposites sides of the semiconductor dies 500, where the optical dies 300 may be arranged along two edges (e.g., two opposites edges or two adjacent edges) of the edges E1, E2, E3 and E4 of the region R3, and the semiconductor dies 1100 may be arranged along the rest of the edges E1, E2, E3 and E4 of the region R3. Alternatively, the semiconductor dies 600 may be arranged at two opposites sides of the semiconductor dies 500, where the optical dies 300 may be arranged along three edges of the edges E1, E2, E3 and E4 of the region R3, and the semiconductor dies 1100 may be arranged along the rest of the edges E1, E2, E3 and E4 of the region R3. Alternatively, the semiconductor dies 600 may be arranged at two opposites sides of the semiconductor dies 500, where the optical dies 300 may be arranged along the edges E1, E2, E3 and E4 of the region R3, and the semiconductor dies 1100 are omitted. For illustrative purposes, only two semiconductor dies 500, four semiconductor dies 600, fourteen semiconductor dies 1100 and eight optical sockets 300 are shown in FIG. 24, however the number of the semiconductor dies 500, the number of the semiconductor dies 600, the number of the semiconductor dies 1100 and the number of the optical dies 300 can be selected and designated based on the demand and design requirement.

In some embodiments, the optical dies 300, the semiconductor dies 500, the semiconductor dies 600, and the semiconductor dies 1100 are placed onto and bonded to the redistribution circuit structure 4300 through a plurality of solder regions 1500 disposed therebetween, where the optical dies 300, the semiconductor dies 500, the semiconductor dies 600 and the semiconductor dies 1100 are electrically coupled to the redistribution circuit structure 4300 through a plurality of solder regions 1500. The bonding process may include a flip-chip bonding process. For example, the semiconductor dies 500 are electrically coupled to each other through the solder regions 1500, the conductive vias 450 and the redistribution circuit structure 430. In such case, the semiconductor dies 500 may be electrically coupled to the semiconductor dies 600 through the solder regions 1500, the conductive vias 450 and the redistribution circuit structure 430, may be electrically coupled to the semiconductor dies 1100 through the solder regions 1500, the conductive vias 450 and the redistribution circuit structure 430, and may be electrically coupled to the optical dies 300 through the solder regions 1500, the conductive vias 450 and the redistribution circuit structure 430. In some embodiments, the semiconductor dies 500 may be electrically coupled to the bridge dies 410 (e.g., 410A, 410B and/or 410C) through the solder regions 1500, the conductive vias 450 and the redistribution circuit structure 430. In some embodiments, the semiconductor dies 500 may be electrically coupled to the conductive pillars 420 through the solder regions 1500, the conductive vias 450 and the redistribution circuit structure 430. In some embodiments, the semiconductor dies 600 may be electrically coupled to the bridge dies 410 (e.g., 410A, 410B and/or 410C) through the solder regions 1500, the conductive vias 450 and the redistribution circuit structure 430. In some embodiments, the semiconductor dies 600 may be electrically coupled to the conductive pillars 420 through the solder regions 1500, the conductive vias 450 and the redistribution circuit structure 430. In some embodiments, the semiconductor dies 1100 may be electrically coupled to the bridge dies 410 (e.g., 410A, 410B and/or 410C) through the solder regions 1500, the conductive vias 450 and the redistribution circuit structure 430. In some embodiments, the semiconductor dies 1100 may be electrically coupled to the conductive pillars 420 through the solder regions 1500, the conductive vias 450 and the redistribution circuit structure 430. In some embodiments, the optical dies 300 may be electrically coupled to the bridge dies 410 (e.g., 410A, 410B and/or 410C) through the solder regions 1500, the conductive vias 450 and the redistribution circuit structure 430. In some embodiments, the optical dies 300 may be electrically coupled to the conductive pillars 420 through the solder regions 1500, the conductive vias 450 and the redistribution circuit structure 430. As shown in FIG. 8, the optical dies 300 are respectively overlapped with the fiber sockets 100, for example. On the other hand, the optical dies 300, the semiconductor dies 500, the semiconductor dies 600, and the semiconductor dies 1100 are electrically isolated from the fiber sockets 100.

In some embodiments, the optical dies 300 are disposed at edge of the semiconductor package SP1, where the optical dies 300 are equipped with an edge coupler. In a non-limiting embodiment of the optical dies 300 as shown in FIG. 8 and FIG. 24 in conjunction with FIG. 9, where one optical die 300 is emphasized as an example of a general structure of the optical dies 300, but the disclosure is not limited thereto. The optical die 300 includes a photonic die (PD) 310, an electrical die (ED) 320 disposed on and electrically coupled to the PD 310, a plurality of conductive vias 330 disposed on and electrically coupled to the PD 310, an insulating encapsulant 340 laterally covering the ED 320 and further covering the PD 310 exposed by the ED 320, and a supporting structure 350 disposed over the ED 320 and the insulating encapsulant 340 through a bonding layer 360 disposed therebetween. As shown in FIG. 8 and FIG. 9, the PD 310 may be disposed between the conductive vias 330 and the insulating encapsulant 340 and between the conductive vias 330 and the ED 320, where the ED 320 and the insulating encapsulant 340 may be disposed between the PD 310 and the supporting structure 350, and the bonding layer 360 may be disposed between the ED 320 and the supporting structure 350 and between the insulating encapsulant 340 and the supporting structure 350. In the disclosure, the PD 310 individually may be referred to as a photonic integrated component or photonic integrated circuit, the ED 320 individually may be referred to as an electrical integrated component or electrical integrated circuit, and the optical die 300 may be referred to as an optical engine.

In some embodiments, the PD 310 includes an electrical portion 300a and at least one optical input/output portion 300b configured to transmit and receive an optical signal (or optical power). The optical signal (or optical power) is, for example, pulsed light, light with continuous wave (CW), the combinations thereof, or the like. The electrical portion 300a of the PD 310 may include semiconductor devices (e.g., active components such as transistors, memories and so on; passive components such as capacitors, resistors, inductors and so on; or combinations thereof), wirings, or conductors for electrical connection. The optical input/output portions 100b of the PD 310 may include semiconductor devices and optical devices for processing, receiving, and/or transmitting the optical signal. For example, the semiconductor devices formed in the optical input/output portions 100b may include transistors, capacitors, photodetectors such as photodiodes, the combination thereof, and the optical devices formed in the optical input/output portions 100b may include an optical network including a modulator 3170, a waveguide 3160, and an edge coupler 3150, that are optically coupled to each other.

The edge coupler(s) (e.g., 3150) allows optical signals and/or optical power to be transferred between the waveguide(s) (e.g., 3160) and a photonic component (e.g., 200 in FIG. 23 and FIG. 24) that is horizontally mounted near a sidewall (e.g., the sidewalls SW300) of the optical dies (e.g., 300). The modulator(s) (e.g., 3170) may be optically coupled to the waveguide(s) (e.g., 3160) to receive electrical signals and generate corresponding optical signals within the waveguide(s) (e.g., 3160) by modulating optical power within the waveguide(s) (e.g., 3160). For example, the photodetector (not shown) may be optically coupled to the waveguide(s) (e.g., 3160) to detect optical signals within the waveguide(s) and generate electrical signals corresponding to the optical signals.

These and other photonic structures are considered within the scope of the disclosure. The optical devices formed in the optical input/output portions 100b may further include I/O couplers, filters, reflector, lasers, detectors, splitters, converters, switches, or the combination thereof. In some embodiments, light-to-electrical conversion devices (e.g., photo-diodes) and/or electrical-to-light conversion devices (e.g., light emitting didoes, lamps, or the like) may be built inside the PD 310. However, the disclosure is not limited thereto; alternatively, the light-to-electrical conversion devices (e.g., photo-diodes) and/or the electrical-to-light conversion devices (e.g., light emitting didoes, lamps, or the like) may be external to and attached to the PD 310.

As shown in FIG. 9, for example, the electrical portions 100a and the optical input/output portions 100b are disposed next to each other along the direction X. Alternatively, the electrical portions 100a and the optical input/output portions 100b are disposed next to each other along the direction Y or/and the directions X and Y.

The PD 310 may include a substrate 3110 having a plurality of semiconductor devices and optical devices formed therein and/or thereon, a plurality of through semiconductor vias (TSV) 3112 embedded in the substrate 3110, an interconnect structure 3120 disposed on the substrate 3110 and the TSVs 3112, a dielectric layer 3130 covering the interconnect structure 3120, and a plurality of conductors 3140 disposed on the interconnect structure 3120 and laterally covered by the dielectric layer 3130. The conductors 3140 are electrically connected to the semiconductor devices and the optical devices formed in and/or on the substrate 3110 through the interconnect structure 3120, and electrically connected to the TSVs 3112 through the interconnect structure 3120, for example. The substrate 3110 may include a semiconductor substrate (e.g., a silicon substrate, a silicon germanium substrate, etc.), a dielectric substrate, or a substrate formed of other semiconductor materials.

The interconnect structure 3120 may include a dielectric structure having a dielectric structure 3122 (e.g., including one or more inter-dielectric layers) and one or more patterned conductive layer 3124 embedded in the dielectric structure 3122 for providing routing function to the active components and the passive components embedded in/on the interconnect structure 3120. In one embodiment, more inter-dielectric layers of the dielectric structure 3122 and one or more patterned conductive layers 3124 are stacked alternately along the direction Z. For example, the inter-dielectric layers may be silicon oxide layers, silicon nitride layers, silicon oxynitride layers, or dielectric layers formed by other suitable dielectric materials, and the inter-dielectric layers may be formed by deposition or the like. For example, the patterned conductive layers may be patterned copper layers or other suitable patterned metal layers, and the patterned conductive layers may be formed by electroplating or deposition. However, the disclosure is not limited thereto. The numbers of the layers of the inter-dielectric layers and the patterned conductive layers may be designated based on the demand and/or design layout, and is not specifically limited to the disclosure.

The conductors 3140 may be made of metal or metal alloy, and the dielectric layer 3130 may be made of a dielectric material. For example, the material of the conductors 3140 is copper (Cu) or other suitable metallic material while the material of the dielectric layer 3130 is silicon oxide (SiOx, where x>0), silicon nitride (SiNx, where x>0), silicon oxynitride (SiOxNy, where x>0 and y>0) or other suitable dielectric material. The dielectric layer 3130 may be formed by depositing a dielectric material layer on the interconnect structure 3120 and patterning the dielectric material layer to form a plurality of openings (not labeled) in the dielectric material layer. The openings formed in the dielectric layer 3130 expose portions of the interconnect structure 3120. After the dielectric layer 3130 is patterned, a conductive material layer may be deposited on the dielectric layer 3130 and the portions of the interconnect structure 3120 exposed by the openings of the dielectric layer 3130. Then, a polishing process (e.g., a mechanical grinding process, a CMP process, an etching process, or a combination thereof) is performed to partially remove the conductive material layer until an illustrated top surface of the dielectric layer 3130 is exposed. After performing the polishing process, the conductors 3140 are formed in the openings of the dielectric layer 3130. As shown in FIG. 9, for example, the illustrated top surfaces of the conductors 3140 and the illustrated top surface of the dielectric layer 3130 are substantially at the same level so as to provide an appropriate surface for bonding. After the polishing process, a cleaning step may be optionally performed, for example to clean and remove the residue generated from the polishing process. However, the disclosure is not limited thereto, and the polishing process may be performed through any other suitable method.

As shown in FIG. 9, the TSVs 3112 are electrically connected to the interconnect structure 3120 and extend downward into the substrate 3110 so to penetrate the substrate 3110 and electrically coupled to the conductive vias 330, for example. In some embodiments, each of the TSVs 3112 is laterally covered by a barrier liner (not shown). For example, the barrier liners are formed between the TSVs 3112 and the substrate 3110. The barrier liners may be formed of a barrier material, such as TiN, Ta, TaN, Ti, or the like. In alternative embodiments, a dielectric liner (not shown) (e.g., silicon nitride, an oxide, a polymer, a combination thereof, etc.) may be further optionally formed between the barrier liners and the substrate 3110. The TSVs 3112, the barrier liners, and the optional dielectric liner may be formed by, but not limited to, forming a plurality of recesses in the substrate 3110; respectively depositing a dielectric material, a barrier material, and a conductive material (e.g., copper, tungsten, aluminum, silver, combinations thereof, or the like) in the recesses; and removing excess materials on the substrate 3110. For example, the recesses of the substrate 3110 are lined with the optional dielectric liner so as to laterally separate the barrier liners lining sidewalls of the TSVs 3112 from the substrate 3110. In some embodiments, the TSVs 3112 are formed by using a via-first approach, which are formed prior to the formation of the interconnect structure 3120. Alternatively, the TSVs 3112 may be formed by using a via-last approach, and may be formed after the formation of the interconnect structure 3120. The barrier liners and/or the additional dielectric liners may be omitted. The interconnect structure 3120 may be referred to as an interconnect, an interconnection structure or an interconnection.

The formation and details of the conductive vias 330 are similar to or substantially identical to the formation and material of the conductive vias 4170 and/or 4180 previously described in FIG. 1 and FIG. 3, and thus are not repeated herein for brevity. As shown in FIG. 8, the optical dies 300 are electrically coupled to the redistribution circuit structure 430 through connecting the conductive vias 330 of the optical dies 300 and the conductive vias 450 by some of the solder regions 1500, for example.

The ED 320 may include a substrate 3210 having a plurality of semiconductor devices formed therein, an interconnect structure 3220 (including a dielectric structure 3222 and one or more patterned conductive layers 3224) disposed on the substrate 3210, a dielectric layer 3230 covering the interconnect structure 3220, and a plurality of conductors 3240 disposed on the interconnect structure 3220 and laterally covered by the dielectric layer 3230. The conductors 3240 are electrically connected to the semiconductor devices formed in the substrate 3210 through the interconnect structure 3220. In some embodiments, the ED 320 may be a logic integrated circuit component, a logic or electric die, a logic or electric chip, a logic or electric integrated circuit to process the electric signal transmitted from the PD 310. The interconnect structure 3220 may be referred to as an interconnect, an interconnection structure or an interconnection. The details of the substrate 3210, the interconnect structure 3220 (including a 3222 and 3224), the dielectric layer 3230 and the conductors 3240 are similar to or substantially identical to the details of the substrate 3110, the interconnect structure 3120, the dielectric layer 3130 and the conductors 3140, and thus are not repeated herein for brevity.

The ED 320 may be picked-up and placed onto the ED 320, where the conductors 3240 of the ED 320 are substantially aligned and in contact with the conductors 3140 of the PD 310. For example, the ED 320 is mounted to the PD 310 by fusion bonding such as a metal-to-metal bonding and a dielectric-to-dielectric bonding. As shown in FIG. 9, the ED 320 may be disposed on the electrical portions 100a of the PD 310, and the optical input/output portions 100b of the PD 310 are not covered by the ED 320.

After bonding the ED 320 to the PD 310, the insulating encapsulant 340 is formed to encapsulate the ED 320 and to cover the optical input/output portions 100b of the PD 310 exposed by the ED 320. The formation of the insulating encapsulant 340 may include, but not limited to, forming an insulating material (not shown) over the PD 310 and the ED 320; and removing the excess insulating material to reveal the ED 320. In some embodiments, the insulating material may be conformally formed by CVD or other suitable deposition processes. The material of the insulating encapsulant 340 may include silicon oxide, silicon nitride, and/or tetraethoxysilane (TEOS). In some embodiments, as shown in FIG. 9, the insulating encapsulant 340 may be a single-layered structure. In some alternative embodiments, the insulating encapsulant 340 may be a multi-layered structure and include a plurality of stacked dielectric layers in form of conformal layer. A planarizing process is performed on the insulating material to remove the excess insulating material to form the insulating encapsulant 340 exposing the ED 320. The planarizing process may include a CMP process, a mechanical grinding process, an etching process, a combination thereof, or other suitable removal processes. As shown in FIG. 8 and FIG. 9, for example, the insulating encapsulant 340 physically contacts the sidewalls of the ED 320. In some embodiments, an illustrated top surface of the insulating encapsulant 340 is substantially levelled with an illustrated top surface of the ED 320. For example, the illustrated top surface of the insulating encapsulant 340 is substantially coplanar to the illustrated top surface of the ED 320. The insulating encapsulant 340 may be referred to as an insulating encapsulation, encapsulation, or encapsulant.

Thereafter, the supporting structure 350 is provided and disposed on the ED 320 and the insulating encapsulant 340 through the bonding layer 360, for example. The supporting structure 350 may be a semiconductor substrate, such as a bulk semiconductor substrate, a semiconductor-on-insulator (SOI) substrate, or the like, which may be doped (e.g., with a p-type or an n-type dopant) or undoped. The supporting structure 350 may be a silicon substrate. Generally, an SOI substrate is a layer of a semiconductor material formed on an insulator layer. The insulator layer may be a buried oxide (BOX) layer, a silicon oxide layer, or the like. For example, the insulator layer is provided on a substrate, typically a silicon or glass substrate. Other substrates, such as a multilayered or gradient substrate may also be used. In some embodiments, the semiconductor material of the supporting structure 350 includes an elementary semiconductor (e.g., silicon or germanium in a crystalline, a polycrystalline, or an amorphous structure, etc.); a compound semiconductor (e.g., silicon carbide, gallium arsenide, gallium phosphide, indium phosphide, indium arsenide, and/or indium antimonide); an alloy semiconductor (e.g., silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and/or gallium indium arsenide phosphide (GaInAsP)); or combinations thereof. The supporting structure 350 may include a dielectric material. For example, the supporting structure 350 is a dielectric substrate, or include a dielectric layer on a semiconductor substrate. Acceptable dielectric materials for dielectric substrates may include oxides such as silicon oxide; nitrides such as silicon nitride; carbides such as silicon carbide; the like; or combinations thereof such as silicon oxynitride, silicon oxycarbide, silicon carbonitride, or the like. The disclosure is not specifically limited, as long as the supporting structure 350 can provide sufficient mechanism strength.

Alternatively, the bonding layer 360 may be omitted, where the supporting structure 350 is disposed on the ED 320 and the insulating encapsulant 340 by fusion bonding such as a dielectric-to-dielectric bonding. The disclosure is not limited thereto.

Back to FIG. 8, in some embodiments, each of the semiconductor dies 500 includes a semiconductor substrate 510 having a surface S510t (may referred to as an active or front surface) and a surface S510b (may referred to as a non-active or rear surface) opposite to the surface S510t, an interconnect structure 520 disposed over the surface S510t of the semiconductor substrate 510, a plurality of conductive vias 530 disposed over and electrically coupled to the interconnect structure 520, where the interconnect structure 520 is disposed between the semiconductor substrate 510 and the conductive vias 530. In some embodiments, the semiconductor substrate 510 is a silicon substrate including active devices (e.g., transistors and/or memories such as N-type metal-oxide semiconductor (NMOS) and/or P-type metal-oxide semiconductor (PMOS) devices, or the like) and/or passive devices (e.g., resistors, capacitors, inductors or the like) formed therein. In some embodiments, such active devices and passive devices are formed in a front-end-of-line (FEOL) process. In an alternative embodiment, the semiconductor substrate 510 is a bulk silicon substrate, such as a bulk substrate of monocrystalline silicon, a doped silicon substrate, an undoped silicon substrate, or a SOI substrate, where the dopant of the doped silicon substrate may be an N-type dopant, a P-type dopant or a combination thereof. The disclosure is not limited thereto. Alternatively, the semiconductor substrate 510 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

In some embodiments, the interconnect structure 520 includes a dielectric structure 522 (including one or more inter-dielectric layers) and one or more patterned conductive layers 524 stacked alternately. For examples, the inter-dielectric layers are silicon oxide layers, silicon nitride layers, silicon oxy-nitride layers, or dielectric layers formed by other suitable dielectric materials, and are formed by deposition or the like. For examples, the patterned conductive layers 524 are patterned copper layers or other suitable patterned metal layers, and are formed by electroplating or deposition. However, the disclosure is not limited thereto. Alternatively, the patterned conductive layers 524 may be formed by a single or dual-damascene method. The number of the inter-dielectric layers of the dielectric structure 522 and the number of the patterned conductive layers 524 may be less than or more than what is depicted in FIG. 8, and may be selected and/or designated depending on the demand and/or design layout; the disclosure is not specifically limited thereto. In some embodiments, the interconnect structure 520 is formed in a BEOL process. In certain embodiments, as shown in FIG. 8, the patterned conductive layers 524 are sandwiched between the inter-dielectric layers of the dielectric structure 522, where a surface of the outermost layer of the patterned conductive layers 524 is exposed by an outermost layer of the inter-dielectric layers of the dielectric structure 522 to connect to later formed component(s) for electrical connection (e.g. with the conductive vias 530), and a surface of an innermost layer of the patterned conductive layers 524 is exposed by an innermost layer of the inter-dielectric layers of the dielectric structure 522 and electrically connected to the active devices and/or passive devices included in the semiconductor substrate 510.

In some embodiments, the conductive vias 530 are formed on the interconnect structure 520 and over the semiconductor substrate 510. In some embodiments, as shown in FIG. 8, the conductive vias 530 each physically contact the surface of the outermost layer of the patterned conductive layers 524 exposed by the outermost layer of the inter-dielectric layers of the dielectric structure 522. Through the interconnect structure 520, the conductive vias 530 are electrically connected to the active devices and/or passive devices included in the semiconductor substrate 510. In some embodiments, the conductive vias 530 in physical contact with the interconnect structure 520 are extended away from the outermost surface of the interconnect structure 520. For simplification, only five conductive vias 530 are presented in each semiconductor die 500 of FIG. 8 for illustrative purposes, however it should be noted that more than five conductive vias 530 may be formed; the disclosure is not limited thereto. As shown in FIG. 8, the semiconductor dies 500 are electrically coupled to the redistribution circuit structure 430 through connecting the conductive vias 530 of the semiconductor dies 500 and the conductive vias 450 by some of the solder regions 1500, for example.

In some embodiments, the conductive vias 530 are formed by photolithography, plating, photoresist stripping processes or any other suitable method. The plating process may include an electroplating plating, an electroless plating, or the like. For example, the conductive vias 530 is formed by, but not limited to, forming a mask pattern (not shown) covering the interconnect structure 520 with opening holes (not shown) corresponding to the surface of the outermost layer of the patterned conductive layers 524 exposed by the outermost layer of the inter-dielectric layers of the dielectric structure 522, forming a metallic material to fill the opening holes formed in the mask pattern to form the conductive vias 530 by electroplating or deposition, and then removing the mask pattern. The mask pattern may be removed by acceptable ashing process and/or photoresist stripping process, such as using an oxygen plasma or the like. In one embodiment, the material of the conductive vias 530 includes a metal material such as copper or copper alloys, or the like.

In some embodiments, in a vertical projection on the surface S510t of the semiconductor substrate 510 along the (stacking) direction Z of the semiconductor substrate 510, the interconnect structure 520 and the conductive vias 530, the conductive vias 530 may independently be in a circle-shape, an ellipse-shape, a triangle-shape, a rectangle-shape, or the like. The shape of the conductive vias 530 is not limited in the disclosure. The shape and number of the conductive vias 530 may be selected and/or designated depending on the demand and/or design layout.

Alternatively, the conductive vias 530 may be formed by, but not limited to, conformally forming a metallic seed layer over the interconnect structure 520, forming a mask pattern (not shown) covering the metallic seed layer with opening holes (not shown) corresponding to the surface of the outermost layer of the patterned conductive layers 524 exposed by the outermost layer of the inter-dielectric layers of the dielectric structure 522, forming a metallic material to fill the opening holes formed in the mask pattern by electroplating or deposition, removing the mask pattern, and then removing the metallic seed layer not covered by the metallic material to form the conductive vias 530. In some embodiments, the metallic seed layer is referred to as a metal layer, which includes a single layer or a composite layer including a plurality of sub-layers formed of different materials. In some embodiments, the metallic seed layer includes titanium, copper, molybdenum, tungsten, titanium nitride, titanium tungsten, combinations thereof, or the like. For example, the metallic seed layer may include a titanium layer and a copper layer over the titanium layer. The metallic seed layer may be formed using, for example, sputtering, PVD or the like.

In some embodiments, the semiconductor dies each 500 further includes a seal ring (not shown) embedded in the interconnect structure 520 to surround the patterned conductive layers 524 inside the dielectric structure 522. Owing to the seal ring, the interconnect structure 520 (e.g., of the dielectric structure 522 and the patterned conductive layers 524) is protected from the physical damages and/or the moistures or hydrogen attacks for the environment. In some embodiments, for each semiconductor die 500, a sidewall of the semiconductor substrate 510 and a sidewall of the interconnect structure 520 are substantially aligned with each other in the direction Z and together constitute a sidewall of the semiconductor die 500.

It is appreciated that, in some embodiments, the semiconductor dies 500 independently described herein may be referred to as a semiconductor chip or an integrated circuit (IC). In some embodiments, the semiconductor dies 500 independently is a logic chip (e.g., a central processing unit (CPU), a graphics processing unit (GPU), a neural network processing unit (NPU), a deep learning processing unit (DPU), a tensor processing unit (TPU), a system-on-a-chip (SoC), an application processor (AP), a system-on-integrated-circuit (SoIC), and a microcontroller); a power management die (e.g., a power management integrated circuit (PMIC) die); a wireless and radio frequency (RF) die; a baseband (BB) die; a sensor die (e.g., a photo/image sensor chip); a micro-electro-mechanical-system (MEMS) die; a signal processing die (e.g., a digital signal processing (DSP) die); a front-end die (e.g., an analog front-end (AFE) die); an application-specific die (e.g., an application-specific integrated circuit (ASIC)); a field-programmable gate array (FPGA); a combination thereof; any suitable logic circuits; or the like. The semiconductor dies 500 independently may be or include a digital chip, an analog chip or a mixed signal chip. The semiconductor dies 500 independently may be a chip or an IC of combination-type, such as a WiFi chip simultaneously including both of a RF chip and a digital chip.

In alternative embodiments, the semiconductor dies 500 independently is an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc. ; a combination thereof; or the like.

In some embodiments, the types of all of the semiconductor dies 500 are identical. In alternative embodiments, the types of some of the semiconductor dies 500 are different from each other, while the types of some of the semiconductor dies 500 are identical types. In further alternative embodiments, the types of all of the semiconductor dies 500 are different. In some embodiments, the sizes of all of the semiconductor dies 500 are the same. In alterative embodiments, the sizes of some of the semiconductor dies 500 are different from each other, while the sizes of some of the semiconductor dies 500 are the same sizes. In further alternative embodiments, the sizes of all of the semiconductor dies 500 are different. In some embodiments, the shapes of all of the semiconductor dies 500 are identical. In alternative embodiments, the shapes of some of the semiconductor dies 500 are different from each other, while the shapes of some of the semiconductor dies 500 are identical. In further alternative embodiments, the shapes of all of the semiconductor dies 500 are different. The types, sizes and shapes of each of the semiconductor dies 500 are independent from each other, and may be selected and designed based on the demand and design layout, the disclosure is not limited thereto.

As shown in FIG. 8 in conjunction with FIG. 24, for example, each of the semiconductor dies 600 includes a carrier die 610 having a surface S610t and a surface S610b opposing to the surface S610t, an interconnect structure 620 (including a dielectric structure 622 and patterned conductive layers 624) disposed over the surface S610t of the carrier die 610 and electrically coupled to the carrier die 610, a plurality of conductive vias 630 disposed over and electrically coupled to the interconnect 620, a plurality of stacking dies 650 disposed over the surface S610b of the carrier die 610 and electrically coupled to the carrier die 610, and an encapsulant 660, where the stacking dies 650 are sequentially stacked on (along the direction Z) and electrically coupled to the carrier die 610, the interconnect structure 620 is disposed between and electrically coupled to the conductive vias 630 and the carrier die 610, and the encapsulant 660 encapsulates the stacking dies 650 and covers the carrier die 610 exposed by the stacking dies 650. In some embodiments, the carrier die 610 is disposed between the encapsulant 660 and the interconnect structure 620 and between the stacking dies 650 and the interconnect structure 620, and the conductive vias 630 is protruded away from a surface of the interconnect structure 620. As shown in FIG. 8, the semiconductor dies 600 are electrically coupled to the redistribution circuit structure 430 through connecting the conductive vias 630 of the semiconductor dies 600 and the conductive vias 450 by some of the solder regions 1500, for example.

It is noted that, each of the carrier die 610 and the stacking dies 650 may further include an interconnect structure (not shown). The carrier die 610 described herein may be referred as a semiconductor chip or an IC. In some embodiments, the carrier die 610 includes one or more digital chips, analog chips or mixed signal chips, such as an ASIC chip, a sensor chip, a wireless and RF chip, a logic chip or a voltage regulator chip. The logic chip may be a CPU, a GPU, a SoC, a microcontroller, or the like. In some embodiments, each of the stacking dies 650 includes a memory die (e.g., a dynamic random-access memory (DRAM) die, static random-access memory (SRAM) die, a synchronous dynamic random-access memory (SDRAM), a resistive random-access memory (RRAM) die, a magnetoresistive random-access memory (MRAM) die, a NAND flash a wide I/O memory (WIO) die, a high bandwidth memory (HBM) die, the like, etc.). That is to say, the semiconductor dies 600 each includes a hybrid memory cube (HMC) module, a HBM module, or the like; in some embodiments. For example, the stacking dies 650 of each semiconductor die 600 may be HBM dies, and the carrier die 610 may be a logic die providing control functionality for these memory dies. The details, formation and material of the interconnect structure 620 (including the dielectric structure 622 and the patterned conductive layers 624) and the conductive vias 630 is similar to or substantially identical to the details, formation and material of the interconnect structure 520 (including the dielectric structure 522 and the patterned conductive layers 524) and the conductive vias 530, and thus are not repeated herein for brevity.

In some embodiments, the material of the encapsulant 660 includes a molding compound, a molding underfill, a resin (such as epoxy), or the like. In some alternative embodiments, the material of the encapsulant 660 includes nitride such as silicon nitride, oxide such as silicon oxide, phosphosilicate glass (PSG), borosilicate glass (BSG), boron-doped phosphosilicate glass (BPSG), a combination thereof, or the like. In yet alternative embodiments, the material of each of the encapsulant 660 includes an organic material (e.g., epoxy, PI, PBO, or the like), or the mixture of inorganic and organic materials (e.g., the mixture of silicon oxide and epoxy, or the like). In some embodiments, the encapsulant 660 may be formed by a molding process, such as a compression molding process. In some alternative embodiments, the encapsulant 660 may be formed through suitable fabrication techniques such as CVD (e.g., high-density plasma chemical vapor deposition (HDPCVD) or plasma-enhanced chemical vapor deposition (PECVD)). As illustrated in FIG. 8, for example, a back (or non-active) surface (not labeled) S600b of the semiconductor die 600 includes a surface of the encapsulant 660 and a surface of outermost stacking die 650, where the surface of the encapsulant 660 and the surface of outermost stacking die 650 are substantially leveled with and substantially coplanar to each other. Alternatively or in addition to, an integrated passives (IPD) die, a voltage regulator (VR) die, a local silicon interconnect (LSI) die with or without deep trench capacitor (DTC) features, a local silicon interconnect die with multi-tier functions such as electrical and/or optical network circuit interfaces, IPD, VR, DTC, or the like may be included to substitute one or some of the semiconductor dies 600 or be further adopted. The type of the semiconductor dies 600 independently may be selected and/or designated depending on the demand and/or design layout, and thus is not specifically limited in the disclosure.

In some embodiments, the types of all of the semiconductor dies 600 are identical. In alternative embodiments, the types of some of the semiconductor dies 600 are different from each other, while the types of some of the semiconductor dies 600 are identical types. In further alternative embodiments, the types of all of the semiconductor dies 600 are different. In some embodiments, the sizes of some of the semiconductor dies 600 are different from each other, while the sizes of some of the semiconductor dies 600 are the same sizes. In alternative embodiments, the sizes of all of the semiconductor dies 600 are the same. In further alternative embodiments, the sizes of all of the semiconductor dies 600 are different. In some embodiments, the shapes of some of the semiconductor dies 600 are different from each other, while the shapes of some of the semiconductor dies 600 are identical. In alternative embodiments, the shapes of all of the semiconductor dies 600 are identical. In further alternative embodiments, the shapes of all of the semiconductor dies 600 are different. The types, sizes and shapes of each of the semiconductor dies 600 are independent from each other, and may be selected and designed based on the demand and design layout, the disclosure is not limited thereto.

In some embodiments, the semiconductor dies 1100 are input/output (I/O) interface dies. For example, the semiconductor dies 500 may be SoCs, the semiconductor dies 600 may be HBM modules, and the semiconductor dies 1100 may be I/O interface dies. The structure, formation and material of the semiconductor dies 1100 may be similar to or substantially identical to the structure, formation and material of the semiconductor dies 500, and thus are not repeated herein. In some embodiments, the semiconductor dies 1100 may be omitted.

Referring to FIG. 10, in some embodiments, sacrificial layers 70 are formed over the sacrificial layers 60 to cover sidewalls SW300 of the optical dies 300, where the sidewalls SW300 are facing away from the region R3. In other words, the optical dies 300 and the sacrificial layers 60 are protected by the sacrificial layers 70. The sacrificial layers 70 may be formed on the optical dies 300 by dispensing process. The sacrificial material forming the sacrificial layers 70 may include polymer, such as acrylic resin, novolak resin, or the like. In the disclosure the sacrificial layers 70 may be referred to as sacrificial features, a protective layers/features or protective polymer layers/features. In some embodiments, the material of the sacrificial layers 70 is the same as the material of the sacrificial layers 60. However, the disclosure is not limited thereto, alternatively, the material of the sacrificial layers 70 may be different from the material of the sacrificial layers 60.

Referring to FIG. 11, in some embodiments, an underfill 710 fills gaps between the semiconductor dies 500 and the redistribution circuit structure 430, between the semiconductor dies 600 and the redistribution circuit structure 430, between the semiconductor dies 1100 and the redistribution circuit structure 430, between the optical dies 300 and the redistribution circuit structure 430, and between the optical dies 300 and the fiber sockets 100. The sidewalls of the conductive vias 450, the sidewalls of the conductive vias 330, the sidewalls of the conductive vias 530, the sidewalls of the conductive vias 630, the sidewalls of the solder regions are wrapped by the underfill 710, where the underfill 710 further extends onto an inner sidewall of the sacrificial layer 70 and an inner sidewall of the redistribution circuit structure 430 facing the inner sidewall of the sacrificial layer 70 and then filled the gap therebetween. The underfill 710 may be any acceptable material, such as a polymer, epoxy resin, molding underfill, or the like, for example. The underfill 710 may be formed by underfill dispensing, a capillary flow process, or any other suitable method. Owing to the underfill 710, bonding strengths between the semiconductor dies 500 and the redistribution circuit structure 430, between the semiconductor dies 600 and the redistribution circuit structure 430, between the semiconductor dies 1100 and the redistribution circuit structure 430, and between the optical dies 300 and the redistribution circuit structure 430 are enhanced.

Referring to FIG. 12 in conjunction with FIG. 24, in some embodiments, the semiconductor dies 500, 600, 1100 and the optical dies 300 are encapsulated in the insulating encapsulant 810, where an illustrated top surface S810 of the insulating encapsulant 810 is substantially level with illustrated top surfaces (e.g., the surfaces S510b) of the semiconductor dies 500, illustrated top surfaces (e.g., the surfaces S600b) of the semiconductor dies 600, illustrated top surfaces of the semiconductor dies 1100 and illustrated top surfaces (e.g., surfaces S300) of the optical dies 300, in some embodiments. In other words, the illustrated top surface S810 of the insulating encapsulant 810 is substantially coplanar to the illustrated top surfaces (e.g., the surfaces S510b) of the semiconductor dies 500, the illustrated top surfaces (e.g., the surfaces S600b) of the semiconductor dies 600, the illustrated top surfaces of the semiconductor dies 1100 and the illustrated top surfaces (e.g., surfaces S300) of the optical dies 300. That is, the semiconductor dies 500, 600, 1100 and the optical dices 300 are accessibly revealed by the insulating encapsulant 810. As shown in FIG. 12 the insulating encapsulant 810 further accessibly reveals the sacrificial layers 70. Alternatively, the semiconductor dies 500, 600, 1100 and the optical dices 300 are not exposed by the illustrated top surface S810 of the insulating encapsulant 810.

For example, the insulating encapsulant 810 laterally encapsulated the semiconductor dies 500, 600, 1100, the optical dices 300 and the sacrificial layers 70 and covers the underfill 710 the redistribution circuit structure 430 exposed by the underfill 710. In some embodiments, the insulating encapsulant 810 is a molding compound formed by a molding process. In some embodiments, the insulating encapsulant 810 include polymers (such as epoxy resins, phenolic resins, silicon-containing resins, or other suitable resins), dielectric materials, or other suitable materials. In an alternative embodiment, the insulating encapsulant 810 may include an acceptable insulating encapsulation material. The insulating encapsulant 810 may further include inorganic filler or inorganic compound (e.g., silica, clay, and so on) which can be added therein to optimize CTE of the insulating encapsulant 810, the disclosure is not limited thereto. The insulating encapsulant 810 may be referred to as an insulating encapsulation, encapsulation, encapsulant, a dielectric encapsulation, or a dielectric encapsulant. For example, the insulating encapsulant 810 is formed by, but not limited to, over-molding semiconductor dies 500, 600, 1100, the optical dices 300 and the sacrificial layers 70 by an insulating encapsulation material, and patterning the insulating encapsulation material to form the insulating encapsulant 810. The insulating encapsulation material may be patterned by a planarizing process until obtaining a substantially flat and planar surface therefrom (e.g., S810). Owing to the insulating encapsulant 810, semiconductor dies 500, 600, 1100 and the optical dices 300 are protected from the damages caused by the external contacts.

The planarizing process is performed by mechanical grinding, CMP, etching or combinations thereof, for example. The etching may include dry etching, wet etching, or a combination thereof. After the planarizing process, a cleaning process may be optionally performed to clean and remove the residue generated from the planarizing process. However, the disclosure is not limited thereto, and the planarizing process may be performed through any other suitable method.

Referring to FIG. 13, in some embodiments, the carrier 50 and the release layer 52 are debonded from the fiber sockets 100 and the insulating encapsulant 460 encapsulating the bridge dies 410 and the conductive pillars 420, and then removed. In some embodiments, a debonding process is performed to remove the carrier 50 and the release layer 52. In one embodiment, the debonding process is a laser debonding process.

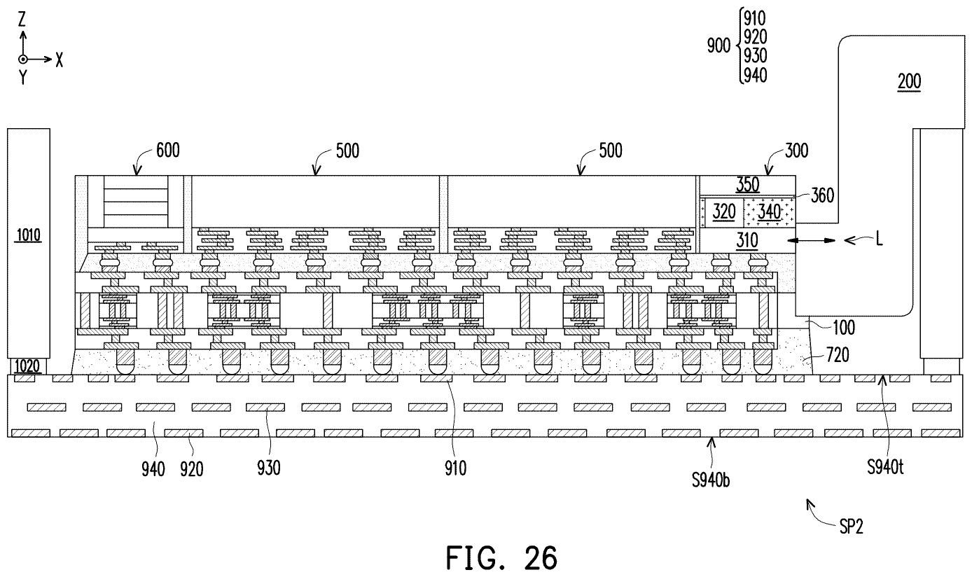

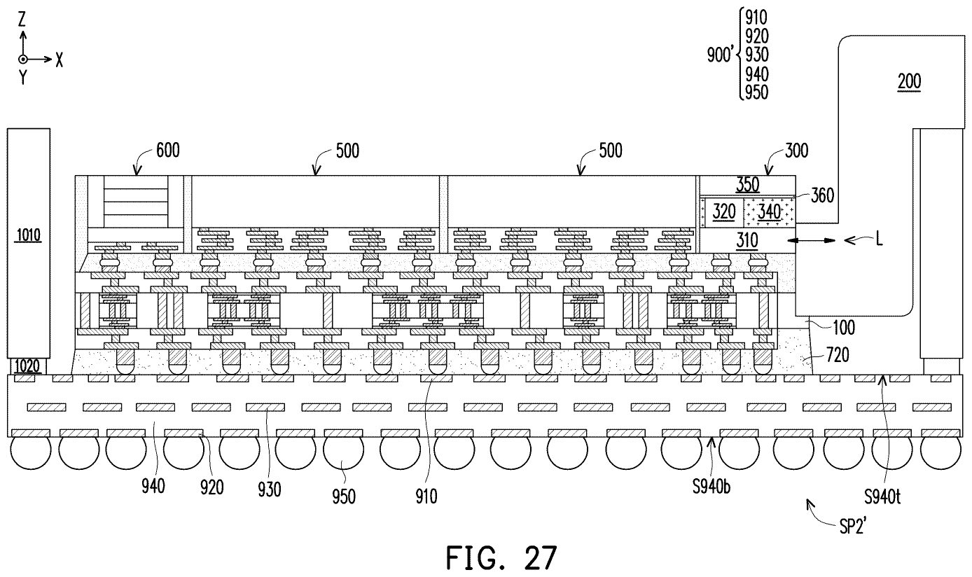

After removing the carrier 50 and the release layer 52, a redistribution circuit structure 440 (including a dielectric structure 442 and one more metallization layers 424) may be formed on the insulating encapsulant 460 encapsulating the bridge dies 410 and the conductive pillars 420 and is electrically connected to the bridge dies 410 (e.g., 410A, 410B and/or 410C) and the conductive pillars 420, as shown in FIG. 13. For example, the insulating encapsulant 460 encapsulating the bridge dies 410 and the conductive pillars 420 is disposed between the redistribution circuit structure 430 and the redistribution circuit structure 440 along the direction Z. The details, formation and material of the redistribution circuit structure 440 (including 442 and 444) are similar to or substantially identical to the details, formation and material of the redistribution circuit structure 430 (including 432 and 434) previously disposed in FIG. 6, and thus are not repeated herein for brevity. In some embodiments, the redistribution circuit structure 440 is further extended onto the fiber sockets 100, see FIG. 13. However, the disclosure is not limited thereto; alternatively, the redistribution circuit structure 440 may be free from the fiber sockets 100, see a semiconductor package SP2 of FIG. 26 and a semiconductor package SP2′ of FIG. 27.

Back to FIG. 13, a plurality of conductive terminals 470 are formed on the redistribution circuit structure 440 to be electrically connected thereto, where the redistribution circuit structure 440 is disposed between the insulating encapsulant 460 and the conductive terminals 470, for example. In some embodiments, each of the conductive terminals 470 include a conductive element 472 and a conductive element 474 disposed on and electrically connected to the conductive element 472, where the conductive element 472 is electrically connected to the outermost layer of the metallization layer 444 exposed by the dielectric structure 442 of the redistribution circuit structure 440. In such case, the conductive elements 472 of the conductive terminals 470 are disposed between the conductive elements 474 of the conductive terminals 470 and the redistribution circuit structure 440.

In some embodiments, the conductive terminals 470 may be formed by the following steps, however the disclosure is not limited thereto. A resist layer (not shown) having openings formed therein is formed on the redistribution circuit structure 440 and corresponds to (e.g., accessibly reveals) the outermost layer of the metallization layer 444 exposed by the dielectric structure 442 of the redistribution circuit structure 440. The conductive elements 472 are formed in the openings formed in the resist layer by deposition or plating. The conductive elements 474e respectively disposed on the conductive elements 472 to form the conductive terminals 470 by dispensing. The resist layer is removed by an acceptable ashing process and/or a photoresist stripping process. In some embodiments, the material of the conductive elements 472 may include copper, copper alloy, or the like; and the material of the conductive elements 474 may include solder or the like. However, the disclosure is not limited thereto, the above method and processes may be substituted by any other suitable method and processes based on the demand.

In some embodiments, the conductive terminals 470 are, for example, micro-bumps, chip connectors (e.g., controlled collapse chip connection (C4) bumps), ball grid array (BGA) balls, solder balls or other connectors. The number of the conductive terminals 470 is not limited to the disclosure, and may be designated and selected based on the demand and the design requirement. When solder is used, the solder may include either eutectic solder or non-eutectic solder. The solder may include lead or be lead-free, and may include Sn—Ag, Sn—Cu, Sn—Ag—Cu, or the like. In the disclosure, for one embodiment, the conductive terminals 470 may be referred to as terminals, conductive connectors or conductors, for connecting with another package or circuit substrate. Or, for another embodiment, the conductive terminals 470 may be referred to as conductive terminals for inputting/outputting electric signals such as electrical signals (with data information) and/or power signals (with power information).

Up to here, an interposer 400 is manufactured, where the interposer 400 includes one or more bridge dies 410 (e.g., 410A, 410B and/or 410C), one or more conductive pillars 420, one or more fiber sockets 100, the insulating encapsulant 460 laterally encapsulated the bridge dies 410 (e.g., 410A, 410B and/or 410C), the conductive pillars 420 and the optical dies 300, the redistribution circuit structure 430, the redistribution circuit structure 440, the conductive vias 450, and the conductive terminals 470. However, the disclosure is not limited thereto; at least one of the redistribution circuit structure 430 or the redistribution circuit structure 440 can be omitted. For one non-limiting example, the interposer 400 may include one or more bridge dies 410 (e.g., 410A, 410B and/or 410C), one or more conductive pillars 420, one or more fiber sockets 100, the insulating encapsulant 460 laterally encapsulated the bridge dies 410 (e.g., 410A, 410B and/or 410C), the conductive pillars 420 and the optical dies 300, the redistribution circuit structure 440, the conductive vias 450, and the conductive terminals 470. For another non-limiting example, the interposer 400 may include one or more bridge dies 410 (e.g., 410A, 410B and/or 410C), one or more conductive pillars 420, one or more fiber sockets 100, the insulating encapsulant 460 laterally encapsulated the bridge dies 410 (e.g., 410A, 410B and/or 410C), the conductive pillars 420 and the optical dies 300, the redistribution circuit structure 430, the conductive vias 450, and the conductive terminals 470. For yet another non-limiting example, the interposer 400 may include one or more bridge dies 410 (e.g., 410A, 410B and/or 410C), one or more conductive pillars 420, one or more fiber sockets 100, the insulating encapsulant 460 laterally encapsulated the bridge dies 410 (e.g., 410A, 410B and/or 410C), the conductive pillars 420 and the optical dies 300, the conductive vias 450, and the conductive terminals 470. However, the disclosure is not limited thereto; in addition to or alternatively, the conductive vias 450 may be omitted. In addition to or alternatively, the conductive terminals 470 may be omitted. In the disclosure, the interposer 400 is equipped with the fiber sockets (e.g., 100), where the fiber sockets (e.g., 100) are arranged along the edges of the interposer 400. In other words, the sidewalls SW100 of the fiber sockets 100, the sidewall SW460 of the insulating encapsulant 460, a sidewall SW430 of the redistribution circuit structure 430 and a sidewall SW440 of the redistribution circuit structure 440 together constitute a sidewall of the interposer 400. In some embodiments, the structure depicted in FIG. 13 can be considered as a structure of chip-on-wafer (CoW). In other words, the structure depicted in FIG. 13 is a CoW structure, for example.

In some embodiments, the optical dies 300 are electrically communicated to the semiconductor dies 500 through the interposer 400 (e.g., at least by the redistribution circuit structure 430 and the conductive vias 450). The optical dies 300 may be further electrically communicated to the semiconductor dies 600 through the interposer 400 (e.g., at least by the redistribution circuit structure 430 and the conductive vias 450). In addition, the optical dies 300 may be further electrically communicated to the semiconductor dies 1100 through the interposer 400 (e.g., at least by the redistribution circuit structure 430 and the conductive vias 450). The disclosure is not limited thereto.

Referring to FIG. 14, in some embodiments, a substrate 900 is provided, and the structure depicted in FIG. 13 (may be referred to as the CoW structure) is bonded to the substrate 900 through the conductive terminals 470. The bonding process may be a flip-chip bonding. As shown in FIG. 14, the semiconductor dies 500, 600, 1100 and the optical dies 300 may be electrically connected to the substrate 900 through the interposer 400.

In some embodiments, the substrate 900 includes a body 940, metallization layers 930 and vias (not shown) interconnected therebetween and disposed in the body 940, and a plurality of bonding pads 910, 920 vertically distributed at two opposite sides of the body 940 and connected to the metallization layers 930 and vias. As shown in FIG. 14, the body 940 has a surface S940t and a surface S940b opposing to the surface S940t, where the bonding pads 910 are accessibly revealed by the surface S940t of the body 940, and the bonding pads 920 are accessibly revealed by the surface S940b of the body 940. The body 940 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. In some alternative embodiments, the body 540 is a SOI substrate, where the SOI substrate may include a layer of a semiconductor material such as epitaxial silicon, germanium, silicon germanium, SOI, silicon germanium on insulator (SGOI), or combinations thereof. In further alternative embodiments, the body 940 is based on an insulating core, such as a fiberglass reinforced resin core. One example core material is fiberglass resin such as flame-retardant class 4 (FR4). Alternatives for the core material may include bismaleimide triazine (BT) resin, or alternatively, other printed circuit board (PCB) materials or films. In yet further alternative embodiments, the body 940 is a build-up film such as Ajinomoto build-up film (ABF) or other suitable laminates. In one embodiment, the body 940 may include active and/or passive devices (not shown), such as transistors, capacitors, resistors, combinations thereof, or the like which may be used to generate the structural and functional requirements of the design for the semiconductor package. The active and/or passive devices may be formed using any suitable methods. However, the disclosure is not limited thereto; in an alternative embodiment, the body 940 may be substantially free of active and/or passive devices.

The metallization layers 930 and vias together form a functional circuitry providing routing for the substrate 900. The metallization layers 930 and vias embedded in the body 940 may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). The bonding pads 910, 920 are used to provide electrical connection with external component(s) for the substrate 900. In some embodiments, the bonding pads 910, 920 are located at two opposite sides of the body 940 along the direction Z and electrically connected to each other through the metallization layers 930 and vias. The formation and material of the bonding pads 910, 920 along with the metallization layers 930 and vias may be similar to or substantially identical to the formation and material of the redistribution circuit structure 430 previously described in FIG. 7, and thus are not repeated herein for brevity. As shown in FIG. 14, for example, the structure depicted in FIG. 13 is connected to the bonding pads 910 of the substrate 900 through the conductive terminals 470.

In some embodiments, one or more surface devices (not shown) may be optionally connected to the substrate 900. The surface devices may be, for example, used to provide additional functionality or programming to the structure depicted in FIG. 13. The surface devices may include surface mount devices (SMDs) or an integrated passive devices (IPDs) that include passive devices such as resistors, inductors, capacitors, jumpers, combinations of these, or the like that are desired to be connected to and utilized in conjunction with the structure depicted in FIG. 13. The surface devices may be disposed at one side or two opposite sides of the substrate in the direction Z. The number of the surface devices are not limited, and may be selected based on the demand and design requirement. The disclosure is not limited thereto. For example, the surface devices are electrically connected to the structure depicted in FIG. 13 through the substrate 900. In some embodiments, the substrate 900 may be referred to as a circuit substrate.

In some embodiments, an underfill 720 is formed on the substrate 900. As shown in FIG. 14, for example, the underfill 720 fills the gap between the structure depicted in FIG. 13 and the substrate 900, and wraps sidewalls of the conductive terminals 470. Owing to the underfill 720, the bonding strength between the structure depicted in FIG. 13 and the substrate 900 is enhanced. The material and formation of the underfill 720 may be the same or similar to the material and formation of underfill 710 previously described in FIG. 11, and thus are not repeated herein for simplicity. However, the disclosure is not limited thereto; alternatively, the underfill 720 may be optionally omitted.

Referring to FIG. 15, in some embodiments, a supporting structure 1010 is provided and mounted to the substrate 900 through a bonding element 1020. In some embodiments, the supporting structure 1010 is attached to the substrate 900 using the bonding element 1020. For example, a bottom surface (not labeled) of the supporting structure 1010 is adhered to an illustrated top surface of the substrate 900 through the bonding element 1020, where the supporting structure 1010 surrounds the CoW structure. In some embodiments, in the plane view (e.g., the X-Y plane) as shown in FIG. 24, the supporting structure 1010 is in a form of a full (continuous) frame annulus having an inner sidewall (not labeled) facing the sidewall of the CoW structure and an outer sidewall (not labeled) opposite to the inner sidewall. For example, the supporting structure 1010 is next to and separated from the CoW structure by a gap, in the plane view. Owing to the supporting structure 1010, the loading effect (e.g., between a central region (disposed with the CoW structure) and a peripherical region surrounding the central region) of the substrate 900 is suppressed, the warpage control is achieved.

The supporting structure 1010 may be referred to as a ring structure. The supporting structure 1010 has a closed, full frame shape of rectangular annulus in the plane view of FIG. 24 for illustrative purposes, however the disclosure is not limited thereto. Alternatively, the supporting structure 1010 may have a closed, continuous frame shape of circular annulus, elliptical annulus, other suitable polygonal annulus in the plane view. Or alternatively, the supporting structure 1010 may have a discontinuous frame shape (e.g., with slits/openings) of rectangular annulus, circular annulus, elliptical annulus, other suitable polygonal annulus in the plane view. In some embodiments, a material of the supporting structure 1010 includes an electrically conductive material, a thermally conductive material or an electrically and thermally conductive material. For example, the material of the supporting structure 1010 includes metals or metal alloys, such as copper, aluminum, cobalt, copper coated with nickel, stainless steel, tungsten, copper-tungsten, copper-molybdenum, silver diamond, copper diamond, aluminum nitride, aluminum silicon carbide or their alloys, stacking of different material combinations thereof, or the like. For example, the supporting structure 1010 is made of a material having high thermal conductivity between about 200 W/(m·K) to about 400 W/(m·K) or more. In the embodiments of which the supporting structure 1010 has the high thermal conductivity, the heat dissipation of the semiconductor package SP1 is further enhanced.

A material of the bonding element 1020 is not particularly limited, and may be chosen as a function of a material used for adhering the substrate 900 and the supporting structure 1010, where the bonding element 1020 has to secure the substrate 900 and the supporting structure 1010 together. In some embodiments, the bonding element 1020 includes an electrically conductive adhesive, a thermally conductive adhesive, or an electrically and thermally conductive adhesive. The material of the bonding element 1020 may include a thermo-curable adhesive, photocurable adhesive, thermally conductive adhesive, thermosetting resin, waterproof adhesive, lamination adhesive or a combination thereof. In alternative embodiments, the bonding element 1020 includes a die attach film (DAF). According to the type of material used, the bonding element 1020 may be formed by deposition, lamination, printing, plating, or any other suitable technique. The bonding element 1020 may further include a filler. For example, the filler includes a metal filler or a metal alloy filler. Through the bonding element 1020, the supporting structure 1010 is physically connect to the substrate 900, for example. The disclosure is not limited thereto. In some embodiments, the material of the bonding element 1020 is or includes dimethyl siloxane, a combination of siloxanes and silicones, or the like.

In certain embodiments, depending on the material of the bonding element 1020, the substrate 900 may be thermally and/or electrically coupled to supporting structure 1010 through the bonding element 1020. Through the bonding element 1020, the supporting structure 1010 may be thermally connected to the substrate 900. Through the bonding element 1020, the supporting structure 1010 may be electrically connected to the substrate 900. Through the bonding element 1020, the supporting structure 1010 may be thermally and electrically connected to the substrate 900. In some embodiments, the shape of the bonding element 1020 and the shape of the supporting structure 1010 in the plane view (e.g., in FIG. 24) share the same pattern/profile.

In some embodiments, after the supporting structure 1010 is mounted onto the substrate 900, an illustrated top surface of the CoW structure is lower than an illustrated top surface of the supporting structure 1010 by a non-distance (e.g., being greater than zero). With such, the supporting structure 1010 further provides a protection for the CoW structure from physical damages during transportation, transferring and/or operation. Although not shown, the illustrated top surface of the CoW structure may be higher than the illustrated top surface of the supporting structure 1010 by a non-distance. Or alternatively, the illustrated top surface of the CoW structure and the illustrated top surface of the supporting structure 1010 may be located at the substantially same height-level. In some embodiments, the supporting structure 1010 is electrically isolated to the CoW structure. In that case, there is no electrical impact (e.g., negative effects such as noises or the like) induced by the supporting structure 1010 to the CoW structure. The structure of FIG. 15 can be considered as a structure of chip-on-wafer-on-substrate (CoWoS). In other words, the structure depicted in FIG. 15 is a CoWoS structure, for example.

In some embodiments, a sidewall SW1020 of the bonding element 1020 is substantially aligned with a sidewall SW1010 of the supporting structure 1010, see FIG. 16. However, the disclosure is not limited thereto; alternatively, the sidewall SW1020 of the bonding element 1020 is protruding out from the sidewall SW1010 of the supporting structure 1010, see FIG. 17.

Referring to FIG. 18, in some embodiments, the sacrificial layers 60 and the sacrificial layers 70 are removed, where the sidewalls SW300 of the optical dies 300 and the fiber sockets 100 (e.g., the base 110 and the engaging structure 120) are accessibly revealed. Up to here, the semiconductor package SP1 is manufactured. The removal process may include an etching process, where the structure of FIG. 15 (e.g., the CoWoS structure) is placed into a bath of an etchant in which the sacrificial layers 60 and the sacrificial layers 70 both have high etching electivity from the etching of the rest of components included in the structure of FIG. 15. In other words, the rest of components included in the structure of FIG. 15 could remain substantially intact during removal of the sacrificial layers 60 and the sacrificial layers 70. For example, if considering the materials of the sacrificial layers 60 and the sacrificial layers 70 independently include acrylic resin, novolak resin or the like and the material of the bonding element 1020 includes dimethyl siloxane, a combination of siloxanes, silicones or the like, the etchant can include propylene glycol monomethylether acetate, propylene glycol monomethylether, diethylene glycol methyl ether, 3-methoxy-3-methyl-1-butanol, tetramethylammonium hydroxide (TMAH), which has an etching selectivity of the sacrificial layers 60, 70 to the bonding element 1020 being 5:1 to 100:1.

In some embodiments of the structure depicted in FIG. 16 is included, after removing the sacrificial layers 60 and the sacrificial layers 70, the sidewall SW1020 of the bonding element 1020 is indent from the sidewall SW1010 of the supporting structure 1010, where the sidewall SW1020 maintains a flat surface, as shown in FIG. 19. However, the disclosure is not limited thereto; alternatively, after removing the sacrificial layers 60 and the sacrificial layers 70, the sidewall SW1020 of the bonding element 1020 is indent from the sidewall SW1010 of the supporting structure 1010, where the sidewall SW1020 is a curved surface, see FIG. 21.

In alternative embodiment of the structure depicted in FIG. 17 is included, after removing the sacrificial layers 60 and the sacrificial layers 70, the sidewall SW1020 of the bonding element 1020 is substantially aligned with the sidewall SW1010 of the supporting structure 1010, where the sidewall SW1020 maintains a flat surface, as shown in FIG. 20. However, the disclosure is not limited thereto; alternatively, after removing the sacrificial layers 60 and the sacrificial layers 70, the sidewall SW1020 of the bonding element 1020 is connected to the sidewall SW1010 of the supporting structure 1010, where the sidewall SW1020 is a curved surface, see FIG. 22.

Referring to FIG. 23 in conjunction with FIG. 24, in some embodiments, a plurality of optical fibers 200 are engaged with the fiber sockets 100 (e.g., located in the openings 120op, which laid on the base 110 and engaged with the engaging structure 120) to have the optical fibers 200 being horizontally mounted to the optical dies 300, where each of the optical fibers 200 is optically coupled to a respective one optical die 300 of the optical dies 300. With the fiber sockets 100, the optical fibers 200 are securely and precisely held onto the semiconductor package SP1, in some embodiments. The lights L transmitted in the optical fibers 200 is projected onto the edge couplers 3150 of the optical dies 300, and/or the lights L emitted out of the edge couplers 3150 of the optical dies 300 is received by the optical fibers 200.

Due to the edge couplers 3150 of the optical dies 300, the bandwidth enlargement and lower polarization sensitivity of optical signals for the semiconductor package SP1 are ensured. Due to the fiber sockets 100, the accuracy and precision of placements of the optical fibers 200 and the alignments between the optical fibers 200 and the optical dies 300 are greatly enhanced and improved. In addition, since the fiber sockets 100 are embedded in the interposer (e.g., 400), the signal transmitting path is shorter, thereby achieving faster data transfer for the semiconductor package SP1 and having small form factor. In some embodiments, the optical fibers 200 may be referred to as horizontally-mounted optical fibers. In some embodiments, the optical fibers 200 may independently include a fiber array unit (FAU). As shown in FIG. 23 and FIG. 24, the optical fibers 200 may further extend onto the supporting structure 1010, and connected to an external device (not shown) which provides the light signal or light power. The optical fibers 200 may be further secured in place using an optional optical glue or other suitable adhesive material. The disclosure is not limited thereto.

In some alternative embodiments, a plurality of conductive terminals 950 are mounted to the substrate 900 and opposite to the supporting structure 1010, for further electrical connection (e.g., to a motherboard, another PCB, a printed wiring board, or the like), see a semiconductor package SP1′ of FIG. 25 and the semiconductor package SP2′ of FIG. 27. In some embodiments, some of the conductive terminals 950 are electrically coupled to the semiconductor dies 500, some of the conductive terminals 950 are electrically coupled to the semiconductor dies 600, some of the conductive terminals 950 are electrically coupled to the semiconductor dies 1100, and/or some of the conductive terminals 950 are electrically coupled to the optical dies 300. The disclosure is not limited thereto. The details, formation and material of the conductive terminals 950 may be similar to the details, formation and material of the conductive terminals 470. For example, the conductive terminals 950 includes BGA balls or solder balls.

In the above embodiments, a core of the interposer 400 are constituted by the bridge dies 410, the conductive pillars 420, the fiber sockets 100 and the insulating encapsulant 460. However, the disclosure is not limited thereto, alternatively, the core of the interposer may be constituted by the bridge dies 410, the conductive pillars 420, the fiber sockets 100 and a silicon substrate, where the bridge dies 410, the conductive pillars 420, the fiber sockets 100 are embedded inside the silicon substrate, where the redistribution circuit structures 430 and 440 are disposed at two opposite sides of the silicon substrate and are electrically connected to the bridge dies 410 and the conductive pillars 420 so to establish a routing structure of the interposer. The formation and material of the conductive pillars 420 may be similar to or substantially identical to the formation and material of the conductive pillars 4120 previous described in FIG. 3, and thus are not repeated herein. In addition, the fiber sockets 100 and the bridge dies 410 may be placed into the silicon substrate by forming opening holes in the silicon substrate for accommodating the fiber sockets 100 and the bridge dies 410, and then the processes of FIG. 7 through FIG. 27 may be performed to manufacture a semiconductor package of the disclosure; as long as the engaging structure of the fiber sockets 100 are accessibly revealed by the silicon substrate in the lateral direction (e.g., the directions X and/or Y).

In accordance with some embodiments, a semiconductor package includes an interposer, a first semiconductor die, and at least one optical die. The interposer includes a plurality of conductive pillars and at least one fiber socket, where the at least one fiber socket is arranged at an edge of the interposer, and a sidewall of the at least one fiber socket is part of a sidewall of the interposer. The first semiconductor die is disposed over and electrically coupled to the interposer. The at least one optical die is disposed over and electrically coupled to the interposer, where the at least one optical die is overlapped with the at least one fiber socket, and the at least one optical die is electrically communicated with the first semiconductor die through the interposer.

In accordance with some embodiments, a semiconductor package includes a first die, a second die, a third die, an interposer, a substrate, and a supporting structure. The first die, the second die and the third die are laterally arranged next to each other, where the third die is equipped with an edge coupler. The interposer is vertically bonded to the first die, the second die and the third die, where the interposer includes a bridge die and a silicon socket laterally next to the bridge die, and the first die and the second die are overlapped with the bridge die and the third die is overlapped with the silicon socket. The substrate is bonded to and electrically coupled to the interposer. The supporting structure is disposed over the substrate and laterally surrounding the interposer, the first die, the second die and the third die.

In accordance with some embodiments, a method of manufacturing a semiconductor package includes the following steps: providing a plurality of conductive pillars, a bridge die and at least one fiber socket having an engaging structure; forming a first sacrificial layer over the at least one fiber socket to cover the engaging structure; encapsulating the plurality of conductive pillars, the bridge die and the at least one fiber socket in a first encapsulant; forming a first redistribution circuit structure over a first side of the first encapsulant, the first redistribution circuit structure further extending onto the plurality of conductive pillars and the bridge die; mounting a first semiconductor die, a second semiconductor die and at least one optical die to the first redistribution circuit structure, the at least one optical die being overlapped with the at least one fiber socket; forming a second sacrificial layer over the first sacrificial layer, the second sacrificial layer further extending onto and covering a sidewall of the at least one optical die; encapsulating the first semiconductor die, the second semiconductor die and the at least one optical die in a second encapsulant; forming a second redistribution circuit structure over a second side of the first encapsulant to form an interposer, the second redistribution circuit structure further extending onto the plurality of conductive pillars and the bridge die, the first side being opposite to the second side; bonding the interposer to a substrate; disposing a supporting structure on the substrate, the supporting structure surrounding the interposer; and removing the first sacrificial layer and the second sacrificial layer to accessibly reveal the engaging structure of the at least one fiber socket and the sidewall of the at least one optical die.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor package, comprising:
an interposer, comprising a plurality of conductive pillars and at least one fiber socket, wherein the at least one fiber socket is arranged at an edge of the interposer, and a sidewall of the at least one fiber socket is part of a sidewall of the interposer;
a first semiconductor die, disposed over and electrically coupled to the interposer; and
at least one optical die, disposed over and electrically coupled to the interposer, wherein the at least one optical die is overlapped with the at least one fiber socket, and the at least one optical die is electrically communicated with the first semiconductor die through the interposer.

2. The semiconductor package of claim 1, wherein the at least one optical die comprises an edge coupler.

3. The semiconductor package of claim 1, wherein the at least one fiber socket comprises:
a base; and
an engaging structure, standing on the base, wherein the engaging structure comprises a first portion and a plurality of second portions connecting to the first portion and protruding away for the first portion, and the plurality of second portions are separated from each other.

4. The semiconductor package of claim 1, wherein the interposer further comprises:
an insulating encapsulant, laterally encapsulating the plurality of conductive pillars, and the at least one fiber socket.

5. The semiconductor package of claim 1, further comprising:
a second semiconductor die, disposed over and electrically coupled to the interposer,
wherein the interposer further comprises:
at least one bridge die, laterally next to the plurality of conductive pillars and the at least one fiber socket; and
an insulating encapsulant, laterally encapsulating the plurality of conductive pillars, the at least one bridge die, and the at least one fiber socket,
wherein the at least one bridge die electrically connects at least two of the first semiconductor die, the second semiconductor die or the at least one optical die.

6. The semiconductor package of claim 5, wherein the first semiconductor die is a logic die and the second semiconductor die is a memory die.

7. The semiconductor package of claim 1, wherein the at least one optical die is electrically isolated from the at least one fiber socket.

8. A semiconductor package, comprising:
a first die, a second die and a third die, laterally arranged next to each other, wherein the third die is equipped with an edge coupler;
an interposer, vertically bonded to the first die, the second die and the third die, the interposer comprising a bridge die and a silicon socket laterally next to the bridge die, wherein the first die and the second die are overlapped with the bridge die and the third die is overlapped with the silicon socket;
a substrate, bonded to and electrically coupled to the interposer; and
a supporting structure, disposed over the substrate and laterally surrounding the interposer, the first die, the second die and the third die.

9. The semiconductor package of claim 8, further comprising:
an insulating encapsulant, laterally encapsulating the first die, the second die and the third die, wherein a sidewall of the third die is exposed by the first insulating encapsulant; and
a bonding element, disposed between the substrate and the supporting structure.

10. The semiconductor package of claim 9, wherein a sidewall of the bonding element is indent from a sidewall of the substrate.

11. The semiconductor package of claim 9, wherein a sidewall of the bonding element is curved.

12. The semiconductor package of claim 8, further comprising:
an underfill, vertically disposed between a gap of the first die and the interposer, a gap of the second die and the interposer, a gap of the third die and the interposer, and a gap of the third die and the silicon socket,
wherein in a cross-section of the semiconductor package, a portion of the silicon socket being protruded out from the sidewall of the third die is free from the underfill.

13. A method of manufacturing a semiconductor package, comprising:
providing a plurality of conductive pillars, a bridge die and at least one fiber socket having an engaging structure;
forming a first sacrificial layer over the at least one fiber socket to cover the engaging structure;
encapsulating the plurality of conductive pillars, the bridge die and the at least one fiber socket in a first encapsulant;
forming a first redistribution circuit structure over a first side of the first encapsulant, the first redistribution circuit structure further extending onto the plurality of conductive pillars and the bridge die;
mounting a first semiconductor die, a second semiconductor die and at least one optical die to the first redistribution circuit structure, the at least one optical die being overlapped with the at least one fiber socket;
forming a second sacrificial layer over the first sacrificial layer, the second sacrificial layer further extending onto and covering a sidewall of the at least one optical die;
encapsulating the first semiconductor die, the second semiconductor die and the at least one optical die in a second encapsulant;
forming a second redistribution circuit structure over a second side of the first encapsulant to form an interposer, the second redistribution circuit structure further extending onto the plurality of conductive pillars and the bridge die, the first side being opposite to the second side;
bonding the interposer to a substrate;
disposing a supporting structure on the substrate, the supporting structure surrounding the interposer; and
removing the first sacrificial layer and the second sacrificial layer to accessibly reveal the engaging structure of the at least one fiber socket and the sidewall of the at least one optical die.

14. The method of claim 13, wherein:
disposing the supporting structure on the substrate comprises disposing the supporting structure on the substrate through a bonding element, and
removing the first sacrificial layer and the second sacrificial layer comprises an etching process, wherein an etching selectivity of the first sacrificial layer and the second sacrificial layer to the bonding element is 5:1 to 100:1.

15. The method of claim 13, wherein prior to encapsulating the first semiconductor die, the second semiconductor die and the at least one optical die in the second encapsulant and after mounting the first semiconductor die, the second semiconductor die and the at least one optical die to the first redistribution circuit structure, the method further comprises:
forming an underfill in a gap of the first semiconductor die and the first redistribution circuit structure, a gap of the second semiconductor die and the first redistribution circuit structure, a gap of the at least one optical die and the first redistribution circuit structure, and a gap of the at least one optical die and the at least one fiber socket.

16. The method of claim 13, wherein prior to disposing the supporting structure on the substrate and after bonding the interposer to the substrate, the method further comprises:
forming an underfill in a gap of the interposer and the substrate, wherein the underfill is extended onto the at least one fiber socket.

17. The method of claim 13, wherein the second redistribution circuit structure further extends onto the at least one fiber socket.

18. The method of claim 17, wherein prior to disposing the supporting structure on the substrate and after bonding the interposer to the substrate, the method further comprises:
forming an underfill in a gap of the interposer and the substrate, wherein the underfill is free from the at least one fiber socket.

19. The method of claim 13, further comprising:
forming a plurality of conductive terminals on the second redistribution circuit structure,
wherein bonding the interposer to the substrate comprises connecting plurality of conductive terminals to the substrate.

20. The method of claim 13, wherein mounting the first semiconductor die, the second semiconductor die and the at least one optical die to the first redistribution circuit structure is performed by flip-chip bonding.
